(19) United States
(12) Patent Application Publication
(10) Pub. No.: US 2003/0161128 A1
(43) Pub. Date: Aug. 28, 2003

(54) Multi-layer wiring device, wiring method and wiring characteristic analyzing/predicting method

(75) Inventor: Hiroo Masuda, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Semiconductor Technology Academic Research Center

(21) Appl. No.: 10/371,426

(22) Filed: Feb. 24, 2003

(30) Foreign Application Priority Data
Feb. 22, 2002 (JP) 2002-046765

(51) Int. Cl. H05K 1/11; H05K 1/14

(52) U.S. Cl. 361/792

(57) ABSTRACT

A multi-layer wiring device includes a plurality of wiring layers which each have a plurality of wirings pitch-arranged in the same direction and are laminated on one another to make pitch-arrangement directions of the wirings of adjacent ones of the wiring layers cross each other. The device further includes a plurality of contact portions which connect the plurality of wirings to each other are provided to permit first and second potentials which are different from each other to be supplied to adjacent ones of the wirings of the plurality of wiring layers.

### CROSS-REFERENCE TO RELATED APPLICATIONS

This application is based upon and claims the benefit of priority from the prior Japanese Patent Application No. 2002-46765, filed Feb. 22, 2002, the entire contents of which are incorporated herein by reference.

### BACKGROUND OF THE INVENTION

1. Field of the Invention

This invention relates to a multi-layer wiring device, wiring method and wiring characteristic analyzing/predicting method and more particularly to a decoupling capacitor formed of a capacitor between parallel extending wirings in a fine-pitch multi-layer wiring structure.

2. Description of the Related Art

In a large scale integrated circuit (LSI) chip, it is so far considered that supply of power supply voltages and currents to various circuits is stable. However, as the number of circuits is increased, the chip area becomes larger. Further, when a current which becomes instantaneously large due to high-speed operation is caused to flow in the circuit, there occurs a problem that the circuit is erroneously operated due to a voltage drop (power supply noise) of the power supply line (VDD wiring, VSS wiring) caused by the inductance and resistance of the wiring. The above problem can be solved to some extent by inserting a decoupling capacitor between the VDD wiring and VSS wiring. That is, in order to solve the above problem, conventionally, a method for inserting a ceramic capacitor between a VDD pin and a VSS pin of an LSI package is used. However, the method has no effect on a reduction in the power supply noise (spike current) occurring in a circuit in the chip which is operated by a large current at high operation speed although it is effective in reducing the power supply noise in an input/output driver.

As another method for reducing the power supply noise, a method using a gate oxide film capacitor of a MOSFET (Metal Oxide Semiconductor Field Effect Transistor) is known. The method is to absorb a spike current by connecting a decoupling capacitor between the VDD wiring and VSS wiring by use of the gate oxide film capacitor of the MOSFET. The method is effective as a method for reducing the power supply noise. However, the method has the disadvantage that the high-frequency characteristic and high-speed operation characteristic are bad. Further, it has the disadvantage that a capacitor with a large gate area is required, the leakage current between the VDD wiring and VSS wiring increases due to the presence of small pin holes in the gate oxide film, and as a result, the power consumption is increased.

Recently, it has been proposed that a large decoupling capacitor is formed on a chip by forming capacitors between parallel extending wirings of a multi-layer wiring structure over a plurality of wiring layers to couple the VDD wiring and VDD wiring to each other (for example, refer to 2001, Symposium on VLSI Circuits Digest of Technical Paper, pp. 201-204). The decoupling capacitor in the above proposal uses capacitances between metal wirings. Therefore, in comparison with the method using the gate oxide film capacitor of the MOSFET, the advantage that a decoupling capacitor having an excellent high-frequency characteristic and high-speed operation characteristic can be provided is attained. However, in the case of the decoupling capacitor in the above proposal, it is impossible to pass a signal line across the capacitance wiring area. As a result, it is only possible to arrange the decoupling capacitor of the above proposal in a peripheral portion of the LSI chip. Further, when an attempt is made to absorb the spike current of a circuit which is driven by a large current at high operation speed, there occurs a serious problem that the decoupling capacitor cannot be arranged near the circuit.

### BRIEF SUMMARY OF THE INVENTION

A first object of this invention is to provide a multi-layer wiring device, wiring method and wiring characteristic analyzing/predicting method by use of which a decoupling capacitor having an excellent high-frequency characteristic and high-speed operation characteristic can be formed, and a signal line can be arranged to cross the capacitance wiring area and can be arranged near a circuit which is driven by a large current at high operation speed in the LSI chip.

A multi-layer wiring device according to a first aspect of the present invention comprises a plurality of wiring layers which each include a plurality of wirings pitch-arranged in the same direction and laminated on one another to make pitch-arrangement directions of the wirings of adjacent ones of the wiring layers cross each other, and a plurality of contact portions which connect the plurality of wirings to one another to permit first and second potentials which are different from each other to be supplied to adjacent wirings of the plurality of wiring layers.

A multi-layer wiring device according to a second aspect of the present invention comprises a wiring element block with a multi-layer wiring structure configured by connecting a plurality of wiring layers which each include a plurality of wirings pitch-arranged in the same direction as one another in a vertical direction by use of a plurality of contact portions, the plurality of wiring layers being laminated on one another to make pitch-arrangement directions of the wirings of adjacent ones of the wiring layers cross each other and first and second potentials which are different from each other being supplied to adjacent wirings of the plurality of wiring layers.

A multi-layer wiring device according to a third aspect of the present invention comprises a wiring element block with a multi-layer wiring structure of m layers configured by connecting n (m≧n≧2) wiring layers which each include p(i) (i=3 to k) wirings pitch-arranged in the same direction as one another in a vertical direction by use of a plurality of contact portions, the n wiring layers being laminated on one another to make pitch-arrangement directions of the wirings of adjacent ones of the wiring layers cross each other, s(j) (s(j)≦p(i)−2, j=1 to k−2) wirings among the p(i) wirings being assigned as wirings which can be used as signal lines and first and second potentials which are different from each other being supplied to adjacent wirings except the signal lines.

A wiring method of a multi-layer wiring device according to a fourth aspect of the present invention is a wiring method of a multi-layer wiring device which includes a wiring element block with a multi-layer wiring structure of m layers configured by laminating n (m≧n≧2) wiring layers on one another by use of a plurality of contact portions to make pitch-arrangement directions of wirings of adjacent ones of the wiring layers cross each other, each of the wiring layers including p(i) (i=3 to k) wirings which are pitch-arranged in the same direction, s(j) (s(j)≦p(i)−2, j=1 to k−2) wirings among the p(i) wirings being assigned as wirings which can be used as signal lines and first and second potentials which are different from each other being supplied to adjacent wirings except the signal lines, and comprises the steps of arranging a plurality of wiring element blocks in a matrix form without overlapping in a power supply wiring area or a signal wiring area between circuit blocks on a semiconductor chip, respectively commonly connecting first and second potential wirings connected to first and second potential supply sources in the plurality of wiring element blocks via first and second power supply lines, connecting signal lines which extend between the plurality of wiring element blocks to one another via block-block connection wirings, and connecting signal lines which extend over upper and lower wiring layers in the same wiring element block to each other via contact wirings.

A wiring characteristic analyzing/predicting method of a multi-layer wiring device according to a fifth aspect of the present invention is a wiring characteristic analyzing/predicting method of a multi-layer wiring device which is configured by arranging a plurality of wiring element blocks each having a multi-layer wiring structure of m layers in a matrix form without overlapping in a power supply wiring area or a signal wiring area between circuit blocks on a semiconductor chip, each of the wiring element blocks being configured by laminating n (m≧n≧2) wiring layers on one another by use of a plurality of contact portions to make pitch-arrangement directions of wirings of adjacent ones of the wiring layers cross each other, each of the wiring layers including p(i) (i=3 to k) wirings which are pitch-arranged in the same direction, s(j) (s(j)≦p(i)−2, j=1 to k−2) wirings among the p(i) wirings being assigned as wirings which can be used as signal lines and first and second potentials which are different from each other being supplied to adjacent wirings except the signal lines, respectively commonly connecting first and second potential wirings connected to first and second potential supply sources in the plurality of wiring element blocks via first and second power supply lines, connecting signal lines which extend between the plurality of wiring element blocks to one another via block-block connection wirings, and connecting signal lines which extend over upper and lower wiring layers in the same wiring element block to each other via contact wirings, and comprises the steps of analyzing an input/output signal propagation characteristic corresponding to a wiring structure of signal lines in the same wiring element block, and deriving a signal propagation characteristic of signal lines extending between the plurality of wiring element blocks based on the result of analysis.

A multi-layer wiring device according to a sixth aspect of the present invention comprises a plurality of wiring element blocks of multi-layer wiring structure with different sizes each configured by laminating a plurality of wiring layers.

According to the multi-layer wiring device, wiring method and wiring characteristic analyzing/predicting method of the present invention, it becomes possible to efficiently and systematically define the way to supply the first or second potential to the adjacent wirings of each wiring layer via through hole contacts.

Further, a wiring can be used as a signal line if supply of the first or second potential to the above wiring is cut off or interrupted by removing the through hole contact. Therefore, it becomes possible to pass the signal line across the capacitance wiring area. As a result, it becomes easy to arrange a decoupling capacitor having an excellent high-frequency characteristic and high-speed operation characteristic near a circuit which is driven by a large current at high operation speed.

Since shield wirings can be provided around the signal line, it becomes difficult for noise to be superimposed on a signal applied to the signal line and an automatic wiring connection algorithm which is least frequently influenced by the erroneous operation due to noise can be attained.

In a case where the wiring element block is laid over the entire surface of the LSI chip, the flatness of the surface of the LSI chip can be easily attained. As a result, it is preferable in enhancing the uniformity and yield of metal wirings in the LSI chip when the metal wirings are formed on the surface of the LSI chip.

Further, the path of the signal line can be freely changed simply by removing or adding the contact which connects the wirings to each other. Therefore, the effect that the designing period for ASICs (Application Specific Integrated Circuits) is shortened can be expected.

In addition, for application as the wiring architecture, if an input/output signal propagation characteristic corresponding to a wiring structure of signal lines in the wiring element block is managed as a library with an emphasis on the characteristic of a wiring cell, it becomes possible to develop a new method for an ASIC, SoC (System on Chip) design based on the library.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a perspective view of the wiring structure of a wiring element block according to a first embodiment of the present invention;

FIGS. 2A and 2B are plan views each showing a disassembled portion of the wiring element block of FIG. 1, for illustrating connection between the wiring layers;

FIGS. 3A and 3B are exploded perspective views showing an example of a case wherein at least one of the wirings of the wiring element block of FIG. 1 is used as a signal line;

FIGS. 4A and 4B are exploded perspective views showing an example of a case wherein the wiring structure of a wiring element block according to a second embodiment of the present invention which is equivalent to that of the wiring element block shown in FIG. 1 is realized with the number of through hole contacts reduced;

FIGS. 5A and 5B are exploded perspective views showing an example of a case wherein at least one of the wirings of the wiring element block shown in FIGS. 4A and 4B is used as a signal line;

FIGS. 6A and 6B are exploded perspective views showing another example of a case wherein the wiring structure of a wiring element block according to a third embodiment of the present invention which is equivalent to that of the wiring element block shown in FIG. 1 is realized with the number of through hole contacts reduced;

FIGS. 7A and 7B are exploded perspective views showing an example of a case wherein at least one of the wirings of the wiring element block shown in FIGS. 6A and 6B is used as a signal line;

FIG. 8 is a plan view of a chip showing an example of the arrangement of a wiring element block according to a fourth embodiment of the present invention;

FIG. 9 is a plan view of a chip showing another example of the arrangement of a wiring element block according to a fourth embodiment of the present invention;

FIG. 10 is a plan view of a multi-layer wiring device for illustrating a wiring method according to a sixth embodiment of the present invention;

FIG. 11 is a plan view showing an example of the layout of signal lines in the multi-layer wiring device shown in FIG. 10;

FIGS. 12A and 12B illustrate a wiring characteristic analyzing/predicting method of a multi-layer wiring device according to a seventh embodiment of the present invention, FIG. 12A being a plan view showing an example of the arrangement of signal lines in the multi-layer wiring device and FIG. 12B being a diagram showing one example of a characteristic library for a certain wiring element block;

FIGS. 13A to 13E are diagrams showing an example of a case wherein a wiring element block according to a seventh embodiment of the present invention is designed to have different sizes;

FIG. 14 is a cross-sectional view showing a basic structure of the wiring element block (minimum unit) shown in FIG. 13A;

FIGS. 15A and 15B are diagrams showing the result of analysis for the plane size of the wiring element block;

FIG. 16A is a view showing an example of a case wherein a signal line is formed of a wide wiring in a ninth embodiment of the present invention and

FIG. 16B is a view showing an example of a case wherein a signal line is formed of a tapered wiring in the ninth embodiment;

FIGS. 17A and 17B are views showing an example of a case wherein VDD and VSS wirings are formed of wide wirings in a tenth embodiment of the present invention;

FIGS. 18A and 18B are views showing an example of a bus signal line according to an eleventh embodiment of the present invention;

FIGS. 19A to 19C are views showing an example of a “T-shaped” wiring according to a twelfth embodiment of the present invention;

FIG. 20A is a view showing an example of a case wherein two metal wirings are used as one pair in a thirteenth embodiment of the present invention and

FIG. 20B is a view showing an example of a case wherein each metal wiring is formed in a stepwise bent form in the thirteenth embodiment;

FIGS. 21A and 21B are views showing an example of a case wherein a signal line is completely shielded in a fourteenth embodiment of the present invention;

FIGS. 22A to 22C are views showing an example of a case wherein an inductor is used in a fifteenth embodiment of the present invention;

FIG. 23A is a view showing an example of a plane capacitor in a sixteenth embodiment of the present invention and

FIG. 23B is a view showing an example of a vertical type capacitor in the sixteenth embodiment;

FIG. 24 is a view showing an example of a 4-bit twist bundle wiring in a seventeenth embodiment of the present invention;

FIGS. 25A and 25B are views showing an example of the wiring structure designed to take a measure to prevent occurrence of errors in an antenna rule in an eighteenth embodiment of the present invention;

FIG. 26 is a view showing an example of a parallel wiring switching wiring according to a nineteenth embodiment of the present invention; and

FIGS. 27A and 27B are views showing a wiring layout design method according to a twentieth embodiment of the present invention.

### DETAILED DESCRIPTION OF THE INVENTION

There will now be described embodiments of this invention with reference to the accompanying drawings.

(First Embodiment)

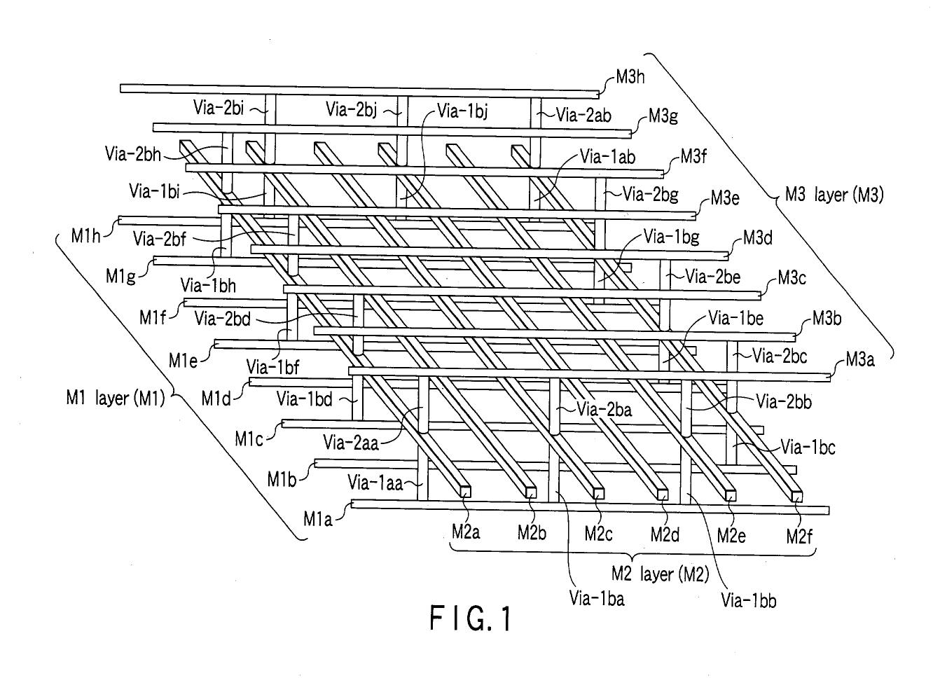

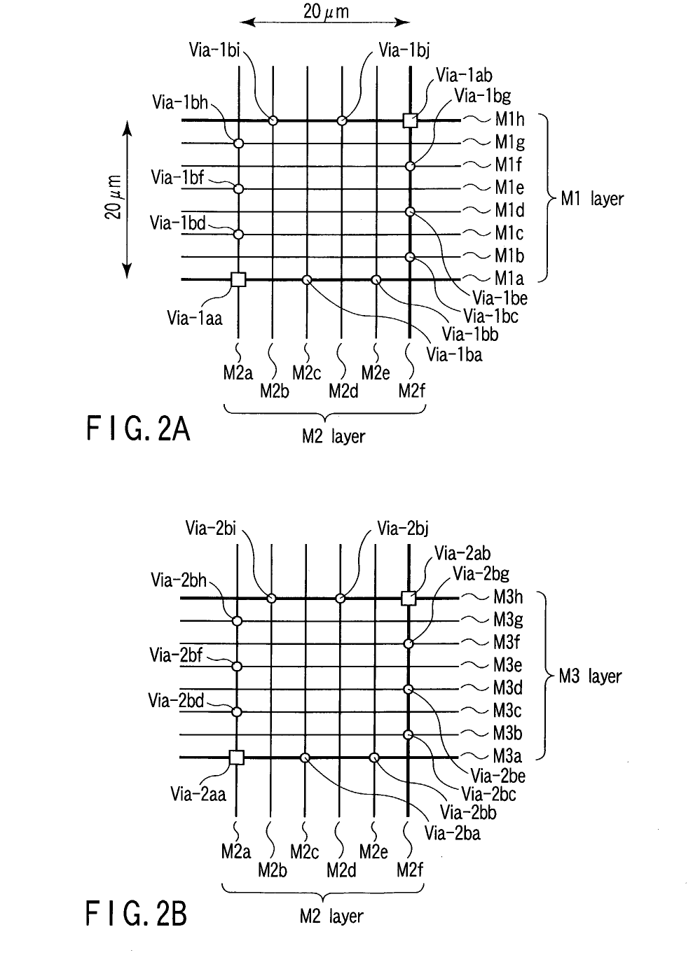

FIG. 1 and FIGS. 2A and 2B show an example of the configuration of a multi-layer wiring device (wiring element block of multi-layer wiring structure) according to a first embodiment of the present invention. FIG. 1 is a perspective view of the wiring structure of the wiring element block. FIGS. 2A and 2B are exploded views of the wiring element block of FIG. 1 and two-dimensionally show the connection relation between the wiring layers. At this time, a case wherein the number (m) of layers of the wiring element block is set to “5” and the number (n) of wiring layers is set to “3” is explained (m≧n≧2). An M1 layer to M3 layer on the lower layer side among layers M1 to M5 (M1 layer to M5 layer) are used as wiring layers and the M4 layer and M5 layer (not shown) on the upper layer side are used as power supply grids. In this example, a case wherein the number p(i) of wirings of each of the M1 layer and M3 layer is set to “8” and the number p(i) of wirings of the M2 layer is set to “6” is shown (i=3 to k).

Among the wiring layers M1 to M3, the M1 layer in the lower position has eight metal wirings M1a, M1b, . . . , M1h. The metal wirings M1a, M1b, . . . , M1h are arranged at the same pitch (pitch-arranged) in a first direction. The M2 layer in the intermediate position has six metal wirings M2a, M2b, . . . , M2f. The metal wirings M2a, M2b, . . . , M2f are pitch-arranged in a second direction which is substantially perpendicular to the first direction. The M3 layer in the upper position has eight metal wirings M3a, M3b, . . . , M3h. The metal wirings M3a, M3b, . . . , M3h are pitch-arranged in a direction which is substantially perpendicular to the second direction, that is, in the first direction which is the same as that of the M1 layer.

As shown in FIG. 2A, the M1 layer and M2 layer are electrically connected to each other via through hole contacts Via-1aa, -1ab which are first contacts (□ marks) and through hole contacts Via-1ba, -1bb, . . . , 1bj which are second contacts (◯ marks). As shown in FIG. 2B, the M2 layer and M3 layer are electrically connected to each other via through hole contacts Via-2aa, -2ab which are first contacts (□ marks) and through hole contacts Via-2ba, -2bb, . . . , 2bj which are second contacts (◯ marks).

That is, the through hole contact Via-1aa is provided at the intersection of the metal wiring M1a of the M1 layer and the metal wiring M2a of the M2 layer and the through hole contact Via-1ab is provided at the intersection of the metal wiring M1h of the M1 layer and the metal wiring M2f of the M2 layer. Likewise, the through hole contact Via-1ba is provided at the intersection of the metal wiring M1a of the M1 layer and the metal wiring M2c of the M2 layer. Further, the through hole contact Via-1bb is provided at the intersection of the metal wiring M1a of the M1 layer and the metal wiring M2e of the M2 layer. Also, the through hole contact Via-1bc is provided at the intersection of the metal wiring M1b of the M1 layer and the metal wiring M2f of the M2 layer. The through hole contact Via-1bd is provided at the intersection of the metal wiring M1c of the M1 layer and the metal wiring M2a of the M2 layer. Further, the through hole contact Via-1be is provided at the intersection of the metal wiring M1d of the M1 layer and the metal wiring M2f of the M2 layer. Also, the through hole contact Via-1bf is provided at the intersection of the metal wiring M1e of the M1 layer and the metal wiring M2a of the M2 layer. The through hole contact Via-1bg is provided at the intersection of the metal wiring M1f of the M1 layer and the metal wiring M2f of the M2 layer. The through hole contact Via-1bh is provided at the intersection of the metal wiring M1g of the M1 layer and the metal wiring M2a of the M2 layer. Further, the through hole contact Via-1bi is provided at the intersection of the metal wiring M1h of the M1 layer and the metal wiring M2b of the M2 layer. Also, the through hole contact Via-1bj is provided at the intersection of the metal wiring M1h of the M1 layer and the metal wiring M2d of the M2 layer.

The through hole contact Via-2aa is provided at the intersection of the metal wiring M2a of the M2 layer and the metal wiring M3a of the M3 layer and the through hole contact Via-2ab is provided at the intersection of the metal wiring M2f of the M2 layer and the metal wiring M3h of the M3 layer. Likewise, the through hole contact Via-2ba is provided at the intersection of the metal wiring M2c of the M2 layer and the metal wiring M3a of the M3 layer. Further, the through hole contact Via-2bb is provided at the intersection of the metal wiring M2e of the M2 layer and the metal wiring M3a of the M3 layer. Also, the through hole contact Via-2bc is provided at the intersection of the metal wiring M2f of the M2 layer and the metal wiring M3b of the M3 layer. The through hole contact Via-2bd is provided at the intersection of the metal wiring M2a of the M2 layer and the metal wiring M3c of the M3 layer. Further, the through hole contact Via-2be is provided at the intersection of the metal wiring M2f of the M2 layer and the metal wiring M3d of the M3 layer. Also, the through hole contact Via-2bf is provided at the intersection of the metal wiring M2a of the M2 layer and the metal wiring M3e of the M3 layer. The through hole contact Via-2bg is provided at the intersection of the metal wiring M2f of the M2 layer and the metal wiring M3f of the M3 layer. The through hole contact Via-2bh is provided at the intersection of the metal wiring M2a of the M2 layer and the metal wiring M3g of the M3 layer. Further, the through hole contact Via-2bi is provided at the intersection of the metal wiring M2b of the M2 layer and the metal wiring M3h of the M3 layer. Also, the through hole contact Via-2bj is provided at the intersection of the metal wiring M2d of the M2 layer and the metal wiring M3h of the M3 layer.

In this case, if the plane size of each of the wiring layers M1, M2, M3 is 20 μm square (20 μm×20 μm), for example, the wiring pitches of the wiring layers M1, M2, M3 in the representative CMOS (Complementary MOS) process of 0.13 μm level are respectively set to 0.36 μm, 0.4 μm, 0.36 μm. Therefore, 55, 50 and 55 metal wirings can be respectively laid on the wiring layers M1, M2, M3 of the above plane size.

VDD potential (first potential) from the VDD potential supply source or VSS potential (second potential) from the VSS potential supply source is always supplied to the metal wirings M1a, M1h, M2a, M2f, M3a, M3h which are arranged on the outermost sides of the wiring layers M1, M2, M3. For example, the VDD potential is supplied to the metal wirings (VDD wirings) M1a, M2a, M3a and the VSS potential is supplied to the metal wirings (VSS wirings) M1h, M2h, M3h. This is attained by sequentially supplying the VDD potential to the M3 layer, M2 layer and M1 layer in this order via the through hole contacts Via-1aa, -2aa, for example. Further, this is attained by sequentially supplying the VSS potential to the M3 layer, M2 layer and M1 layer in this order via the through hole contacts Via-1ab, -2ab, for example.

The VDD and VSS potentials are alternately supplied to the metal wirings (s(j) wirings which can be used as signal lines) M1b to M1g, M2b to M2e, M3b to M3g other than the metal wirings which are arranged on the outermost sides of the wiring layers M1, M2, M3 (s(j)≦p(i)−2, j=1 to k−2). For example, the VDD potential is supplied to the metal wirings (odd-numbered wirings) M1c, M1e, M1g, M2c, M2e, M3c, M3e, M3g and the VSS potential is supplied to the metal wirings (even-numbered wirings) M1b, M1d, M1f, M2b, M2d, M3b, M3d, M3f. This is attained by sequentially supplying the VDD potential to the M3 layer, M2 layer and M1 layer in this order via the through hole contacts Via-1ba, -1bb, -1bd, -1bf, -1bh, -2ba, -2bb, -2bd, -2bf, -2bh, for example. Further, this is attained by sequentially supplying the VSS potential to the M3 layer, M2 layer and M1 layer in this order via the through hole contacts Via-1bc, -1be, -1bg, -1bi, -1bj, -2bc, -2bc, 2be, -2bg, -2bi, -2bj, for example.

In this case, it is assumed that the capacitance between adjacent ones of the metal wirings (capacitance between parallel extending wirings) formed by the CMOS process of 0.13 μm level is 0.26 fF/μm. Then, if the size of the capacitance wiring area is 20 μm square, a high-speed decoupling capacitor of approximately 0.2 pF can be attained. Further, the sheet resistance of the wiring is 0.07 Ω/square, the wiring time constant is 0.1 ps or less and the response characteristic is sufficiently high. Therefore, in the case of the wiring element block of the present embodiment, it is possible to easily form a large decoupling capacitor by using a capacitor between adjacent ones of the metal wirings (capacitance between parallel extending wirings having a fine pitch multi-layer wiring structure) in each of the wiring layers M1, M2, M3 as a decoupling capacitor between VDD and VSS. Since the large decoupling capacitor is formed by use of the capacitor between the parallel extending wirings, the effect becomes more significant as the fine patterning process technology is further developed.

Further, in the wiring element block of the present embodiment, it is possible to use part of the metal wirings in each of the wiring layers M1, M2, M3 as signal lines. That is, all of the metal wirings other than the metal wirings which are arranged on the outermost sides of the wiring layers M1, M2, M3, that is, VDD wirings M1a, M2a, M3a and VSS wirings M1h, M2f, M3H can be used as signal lines.

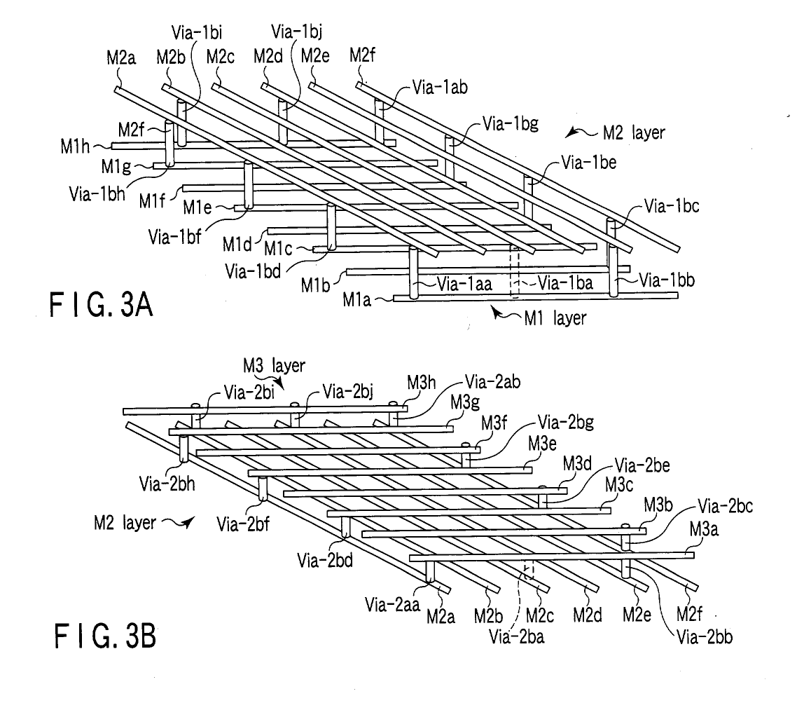

FIGS. 3A and 3B show an example of a case wherein at least one of the wirings of the wiring element block of FIG. 1 is used as a signal line. FIG. 3A shows the connection relation between the M1 layer and the M2 layer and FIG. 3B shows the connection relation between the M2 layer and the M3 layer.

In the wiring element block, for example, the metal wiring M2c can be used as a signal line by removing the through hole contacts Via-1ba, -2ba to cut off or interrupt supply of the VDD potential to the metal wiring M2c (to set the metal wiring M2c into an electrically floating state). In this case, the VDD potential or VSS potential is supplied to the other metal wirings without fail. Therefore, the metal wiring M2c used as the signal line is shielded by electrodes used in a DC manner. That is, the metal wiring M2c is shielded by the metal wirings (shield wirings) which are provided adjacent thereto and set at the fixed potential of VDD or VSS and has a great advantage that it is excellent in the signal line noise (crosstalk) resistance.

Thus, in addition to the metal wiring M2c, any desired metal wiring can be used as a signal line which crosses the capacitance wiring area by interrupting supply of the VDD potential or VSS potential to the desired metal wiring. As a result, a wiring element block can be arranged near a circuit which is driven by a large current at high operation speed in the LSI chip.

As described above, in the present embodiment, it is possible to realize a multi-layer wiring device which has a large decoupling capacitor and in which passage of a signal line which cannot be attained in the conventional structure can be made possible. That is, a serious problem that the signal line cannot pass across the capacitance wiring area which is a defect in the prior art can be solved and a high-speed decoupling capacitor can be arranged in various positions in the LSI chip.

Particularly, the possibility that the multi-layer wiring device of the above configuration is most frequently used in the high frequency and high speed CMOS field, for example, is strong. Further, it can be widely used as the wiring architecture in the system LSI having a large chip area.

In the first embodiment, a case wherein the wiring element block has the five-layered structure (the number m of layers is set to “5”) and the M1 layer, M2 layer and M3 layer among the five layers are used as the wiring layers is explained. However, this is not limitative and, for example, the M1 layer, M2 layer, M3 layer and M4 layer can be used as the wiring layers. Further, the number m of layers is not limited to “5”.

(Second Embodiment)

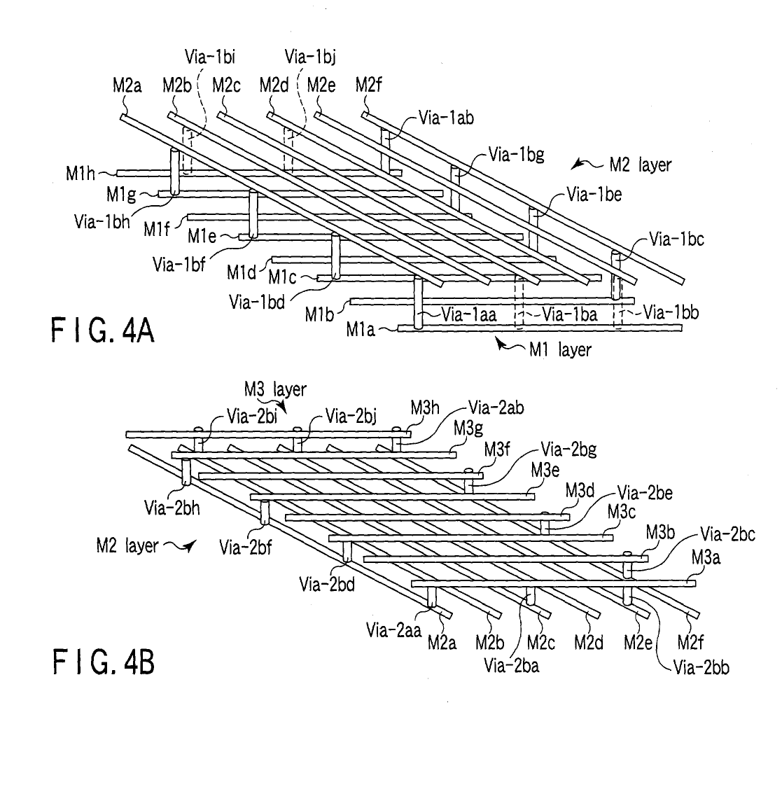

FIGS. 4A and 4B show an example of the configuration of a multi-layer wiring device (wiring element block of multi-layer wiring structure) according to a second embodiment of the present invention. In this case, an example of a case wherein the wiring structure which is equivalent to that of the wiring element block shown in FIG. 1 is realized by reducing the number of through hole contacts between the wiring layers M1 and M2 is explained.

As shown in FIG. 4A, for example, the wiring structure which is equivalent to that of the wiring element block shown in FIG. 1 can also be realized by removing the through hole contacts Via-1ba, -1bb, -1bi, -1bj. That is, when the through hole contact Via-1ba is removed, supply of the VDD potential to the metal wiring M2c is carried out from the metal wiring M3a via the through hole contact Via-2ba (refer to FIG. 4B). Likewise, when the through hole contact Via-1bb is removed, supply of the VDD potential to the metal wiring M2e is carried out from the metal wiring M3a via the through hole contact Via-2bb (refer to FIG. 4B). Further, when the through hole contact Via-1bi is removed, supply of the VSS potential to the metal wiring M2b is carried out from the metal wiring M3h via the through hole contact Via-2bi (refer to FIG. 4B). Likewise, when the through hole contact Via-1bj is removed, supply of the VSS potential to the metal wiring M2d is carried out from the metal wiring M3h via the through hole contact Via-2bj (refer to FIG. 4B).

Thus, in the wiring element block shown in FIG. 1, the through hole contacts Via-1ba, -1bb, -1bi, -1bj can be removed, and as a result, the process can be simplified.

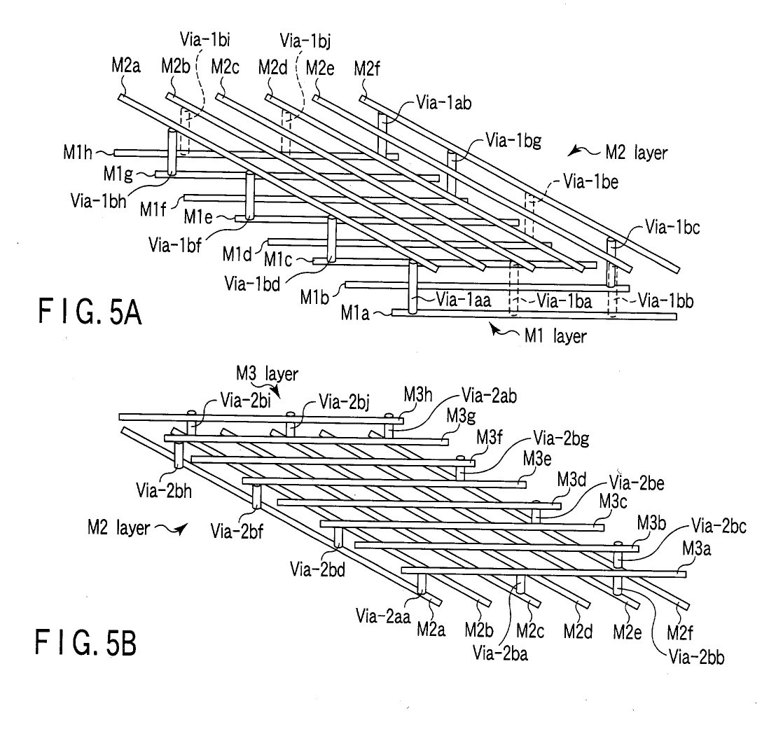

Further, as shown in FIGS. 5A and 5B, as in the case of the first embodiment, in the wiring element block according to the second embodiment, at least one of the metal wirings can be used as a signal line. That is, in the structure in which the through hole contacts Via-1ba, -1bb, -1bi, -1bj are removed, for example, as shown in FIG. 5A, the metal wiring M1d can be used as a signal line by removing the through hole contact Via-1be and interrupting supply of the VSS potential to the metal wiring M1d. Also, in the case of this example, the VDD potential or VSS potential is supplied to the other metal wirings without fail. Therefore, the metal wiring M1d used as the signal line becomes highly resistant to signal line noise.

The metal wiring used as the signal line is not limited to the metal wiring M1d. Any desired metal wiring other than the VDD wiring and VSS wiring can be used as a signal line which crosses the capacitance wiring area by interrupting supply of the VDD potential or VSS potential to the metal wiring.

(Third Embodiment)

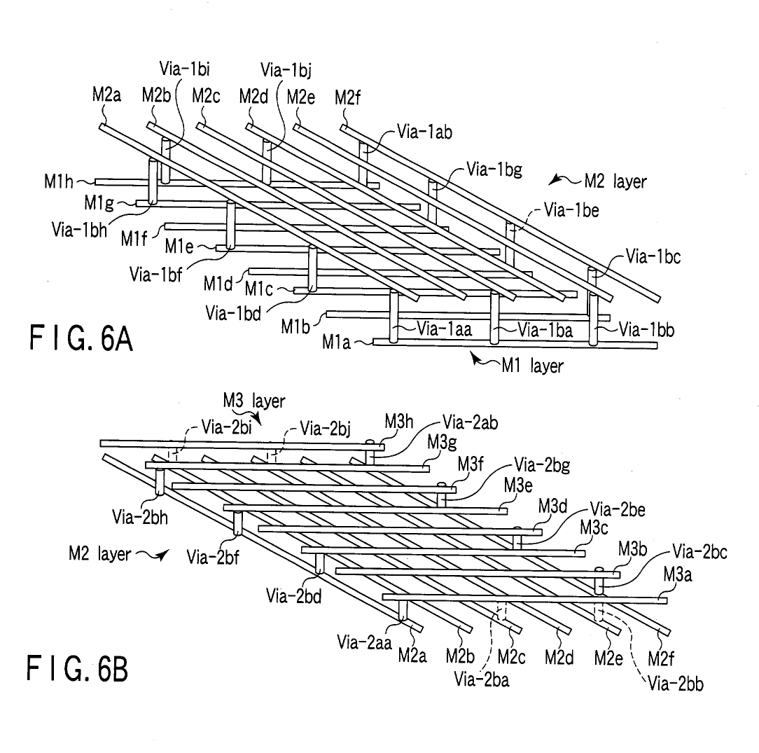

FIGS. 6A and 6B show an example of the configuration of a multi-layer wiring device (wiring element block of multi-layer wiring structure) according to a third embodiment of the present invention. In this example, a case wherein the wiring structure which is equivalent to that of the wiring element block shown in FIG. 1 is realized by reducing the number of through hole contacts between the wiring layers M2 and M3 is explained.

For example, as shown in FIG. 6B, the wiring structure which is equivalent to that of the wiring element block shown in FIG. 1 can be realized by removing the through hole contacts Via-2ba, -2bb, -2bi, -2bj. That is, when the through hole contact Via-2ba is removed, supply of the VDD potential to the metal wiring M2c is carried out from the metal wiring M1a via the through hole contact Via-1ba (refer to FIG. 6A). Likewise, when the through hole contact Via-2bb is removed, supply of the VDD potential to the metal wiring M2e is carried out from the metal wiring M1a via the through hole contact Via-1bb (refer to FIG. 6A). Further, when the through hole contact Via-2bi is removed, supply of the VSS potential to the metal wiring M2b is carried out from the metal wiring M1h via the through hole contact Via-1bi (refer to FIG. 6A). Likewise, when the through hole contact Via-2bj is removed, supply of the VSS potential to the metal wiring M2d is carried out from the metal wiring M1h via the through hole contact Via-1bj (refer to FIG. 6A).

Thus, in the wiring element block shown in FIG. 1, the through hole contacts Via-2ba, -2bb, -2bi, -2bj can be removed, and as a result, the process can be simplified.

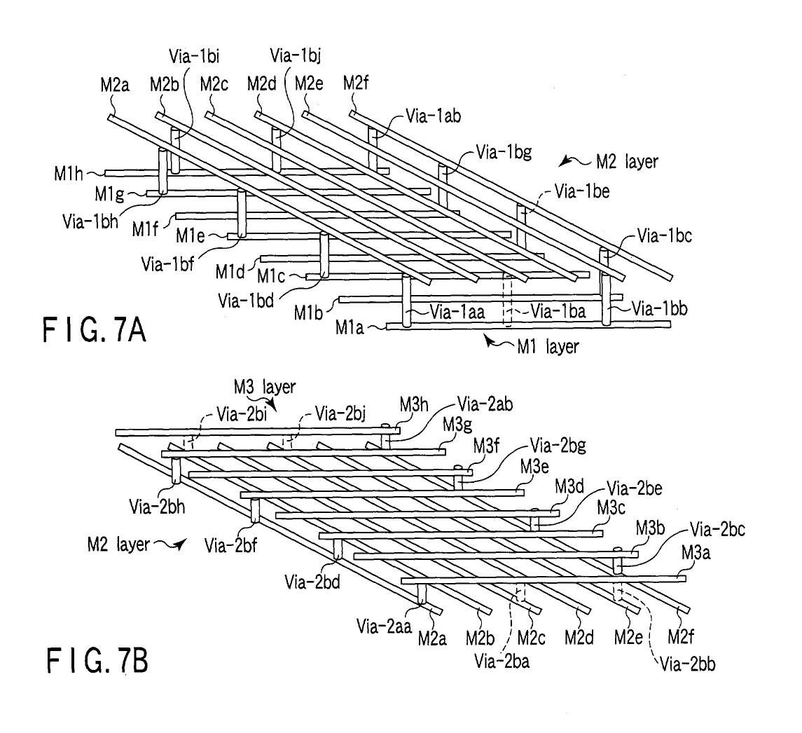

Further, as shown in FIGS. 7A and 7B, as in the case of the first embodiment, in the wiring element block according to the third embodiment, at least one of the metal wirings can be used as a signal line. That is, in the structure in which the through hole contacts Via-2ba, -2bb, -2bi, -2bj are removed, for example, as shown in FIG. 7A, the metal wiring M2c can be used as a signal line by removing the through hole contact Via-1ba and interrupting supply of the VDD potential to the metal wiring M2c. Also, in the case of this example, the VDD potential or VSS potential is supplied to the other metal wirings without fail. Therefore, the metal wiring M2c used as the signal line becomes highly resistant to signal line noise.

The metal wiring used as the signal line is not limited to the metal wiring M2c. Any desired metal wiring other than the VDD wiring and VSS wiring can be used as a signal line which crosses the capacitance wiring area by interrupting supply of the VDD potential or VSS potential to the metal wiring.

(Fourth Embodiment)

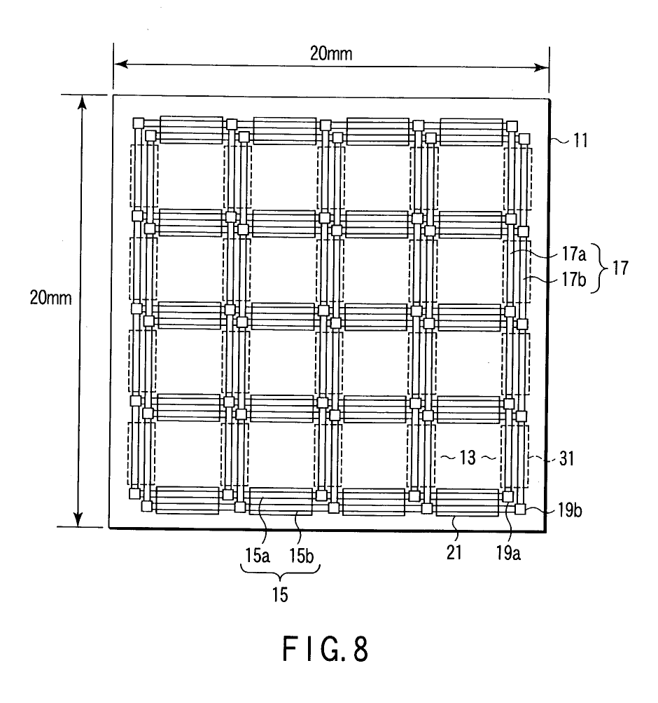

FIG. 8 shows an example of the arrangement of a multi-layer wiring device (wiring element block of multi-layer wiring structure) according to a fourth embodiment of the present invention. In this example, a case wherein a plurality of wiring element blocks are buried under grid sides of power grids (which are hereinafter referred to as Pw grids) of 100 μm square arranged in an LSI chip having a plane size of 20 mm square is explained.

As shown in FIG. 8, for example, in an LSI chip 11 with five-layered structure, if the fourth and fifth layers on the upper side are used as power supply grids, 16 wiring areas 13 are arranged in a matrix form on the uppermost fifth layer. Five sets of first VDD, VSS pairs 15 and five sets of second VDD, VSS pairs 17 are arranged on the peripheral portions of the wiring areas 13 corresponding to the grid sides of the Pw grid. Each of the first VDD, VSS pairs 15 includes a VDD power supply line 15a and VSS power supply line 15b formed on the fourth layer and arranged in a first direction (row direction) of the LSI chip 11. Each of the second VDD, VSS pairs 17 includes a VDD power supply line 17a and VSS power supply line 17b formed on the fifth layer and arranged in a second direction (column direction) substantially perpendicular to the first direction of the LSI chip 11.

The VDD power supply lines 15a of the first VDD, VSS pairs 15 and the VDD power supply lines 17a of the second VDD, VSS pairs 17 are connected together via corresponding through hole contacts 19a at respective intersections. Further, the VSS power supply lines 15b of the first VDD, VSS pairs 15 and the VSS power supply lines 17b of the second VDD, VSS pairs 17 are connected together via corresponding through hole contacts 19b at respective intersections.

An wiring element block 21 with the configuration shown in FIG. 1, for example, is buried under each of the first VDD, VSS pairs 15. That is, twenty wiring element blocks 21 with the five-layered structure having three layers of M1 layer, M2 layer, M3 layer on the lower layer side as wiring layers are buried for each row (100 blocks in total). In the case of this example, the M4 layer, M5 layer of the wiring element block 21 are also used as the fourth, fifth layers of the LSI chip 11. Further, twenty wiring element blocks 31 with the five-layered structure having four layers of M1 layer, M2 layer, M3 layer, M4 layer (not shown) as wiring layers are buried under the second VDD, VSS pairs 17 for each column (100 blocks in total). In the case of this example, the M5 layer of the wiring element block 31 is also used as the fifth layer of the LSI chip 11.

If a plurality of Pw grids of 100 μm square are arranged in the entire portion of the LSI chip 11 of 20 mm square, a decoupling capacitor with 200 nF in total can be formed between the VDD power supply line and the VSS power supply line by burying the wiring element blocks 21, 31 under the grid sides of the respective Pw grids. In this case, the wiring time constant of the decoupling capacitor is 1 ps or less and it is possible to easily absorb high-speed current noise and capacitive coupling noise.

In the present embodiment, for example, the first VDD, VSS pair 15 can be formed by use of the fifth layer of the LSI chip 11 and the second VDD, VSS pair 17 can be formed by use of the fourth layer. In this case, the wiring element block 31 is buried under the first VDD, VSS pair 15 and the wiring element block 21 is buried under the second VDD, VSS pair 17.

Further, if the plane size of the wiring element blocks 21, 31 is 20 μm square, the wiring time constant thereof is 1 ps or less and it is sufficiently high response speed when taking it into consideration that they are used as decoupling capacitors. However, the above size is not limitative. For example, the response characteristic of approximately 100 GHz is required in order to cope with the clock response of 10 GHz, and even if the plane size of the wiring element block is increased to approximately 50 μm square in order to meet the above requirement, no problem arises. However, the above wiring time constant is calculated on the assumption that the CMOS process of 0.13 μm level is used and it is well known in the art that it varies depending on the technical level.

(Fifth Embodiment)

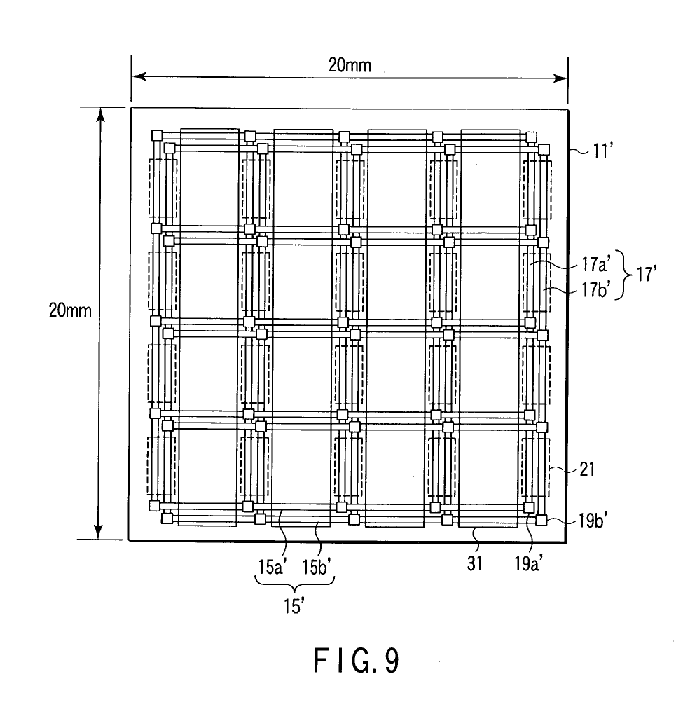

FIG. 9 shows another example of the arrangement of a multi-layer wiring device (wiring element block of multi-layer wiring structure) according to a fifth embodiment of the present invention. In this example, a case wherein a plurality of wiring element blocks are buried under the entire surface of an LSI chip having a plane size of 20 mm square is explained.

As shown in FIG. 9, for example, in an LSI chip 11′ with five-layered structure, if the fourth and fifth layers on the upper layer side are used as power supply grids, a plurality of Pw grids having a plane size of 100 μm square are arranged on the uppermost fifth layer. Five sets of first VDD, VSS pairs 15′ and five sets of second VDD, VSS pairs 17′ are arranged on the grid sides of each Pw grid. Each of the first VDD, VSS pairs 15′ includes a VDD power supply line 15a′ and VSS power supply line 15b′ formed on the fifth layer and arranged in a first direction (row direction) of the LSI chip 11′. Each of the second VDD, VSS pairs 17′ includes a VDD power supply line 17a′ and VSS power supply line 17b′ formed on the fourth layer and arranged in a second direction (column direction) substantially perpendicular to the first direction of the LSI chip 11′.

The VDD power supply lines 15a′ of the first VDD, VSS pairs 15′ and the VDD power supply lines 17a′ of the second VDD, VSS pairs 17′ are connected together via corresponding through hole contacts 19a′ at respective intersections. Further, the VSS power supply lines 15b′ of the first VDD, VSS pairs 15′ and the VSS power supply lines 17b′ of the second VDD, VSS pairs 17′ are connected together via corresponding through hole contacts 19b′ at respective intersections.

Twenty wiring element blocks 21 with the configuration shown in FIG. 1, for example, are buried under the second VDD, VSS pairs 17′ (100 blocks in total). In the case of this example, the M4 layer, M5 layer of the wiring element block 21 are also used as the fourth, fifth layers of the LSI chip 11′. Further, 100 wiring element blocks 31 with the five-layered structure having four layers of M1 layer, M2 layer, M3 layer, M4 layer (not shown) as wiring layers are buried under portions between the second VDD, VSS pairs 17′ (containing the first VDD, VSS pairs 15′ and corresponding to the wiring areas 13 of FIG. 8) (400 blocks in total). In the case of this example, the M5 layer of the wiring element block 31 is also used as the fifth layer of the LSI chip 11′.

If a plurality of Pw grids of 100 μm square are arranged in the entire portion of the LSI chip 11 of 20 mm square, the capacitance of a decoupling capacitor formed at this time can be greatly increased in comparison with that in the fourth embodiment by burying the wiring element blocks 21, 31 under the entire surface of the LSI chip 11′. Therefore, a variation in the power supply voltage can be suppressed and the operation of the circuit in the LSI chip 11′ can be made extremely stable.

Further, when the wiring element blocks 21, 31 are buried under the entire surface of the LSI chip 11′, it becomes unnecessary to use a process for arranging fine rectangular wiring patterns (dummy patterns) all over an area in which the metal wirings are arranged with low density in order to keep the film thickness of the metal wiring constant in the CMP (Chemical Mechanical Polishing) technique used when wiring layers are formed. As a result, occurrence of problems such as deterioration of the wiring signal transmission performance and a design error in the wiring mask design can be prevented. Further, this is effective in enhancing the uniformity of the process and enhancing the resistance to electrostatic breakdown.

In the present embodiment, for example, the first VDD, VSS pair 15′ can be formed by use of the fourth layer of the LSI chip 11′ and the second VDD, VSS pair 17′ can be formed by use of the fifth layer. In this case, the wiring element block 21 are buried under the first VDD, VSS pairs 15′ and the wiring element blocks 31 are buried under portions between the first VDD, VSS pairs 15′. In either case, it is better (efficient) to increase the capacitance of the decoupling capacitor by arranging a larger number of wiring element blocks 31 having a larger number of wiring layers.

(Sixth Embodiment)

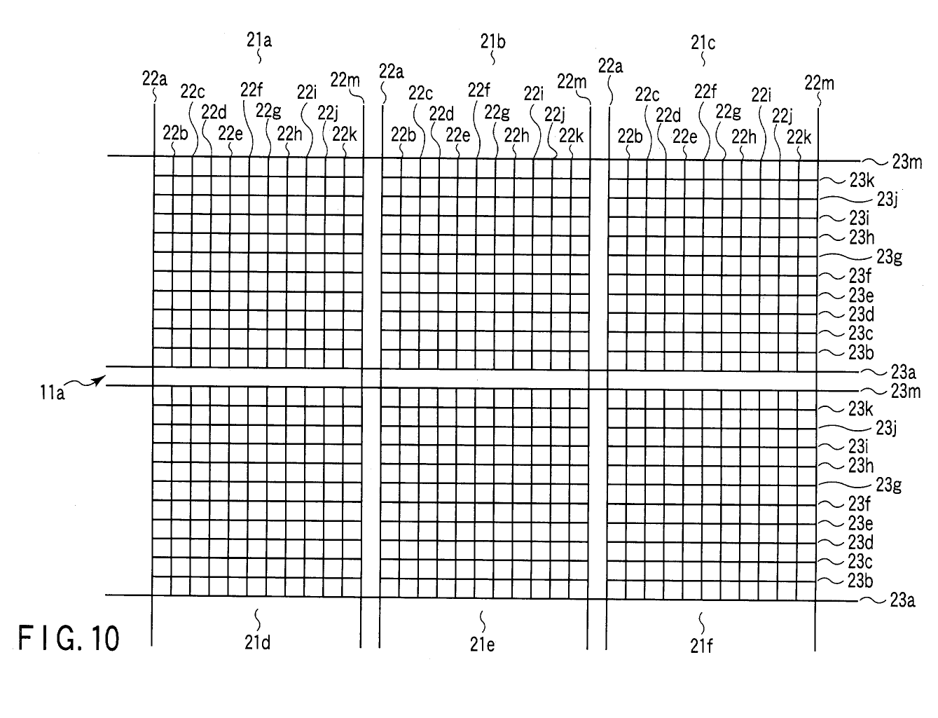

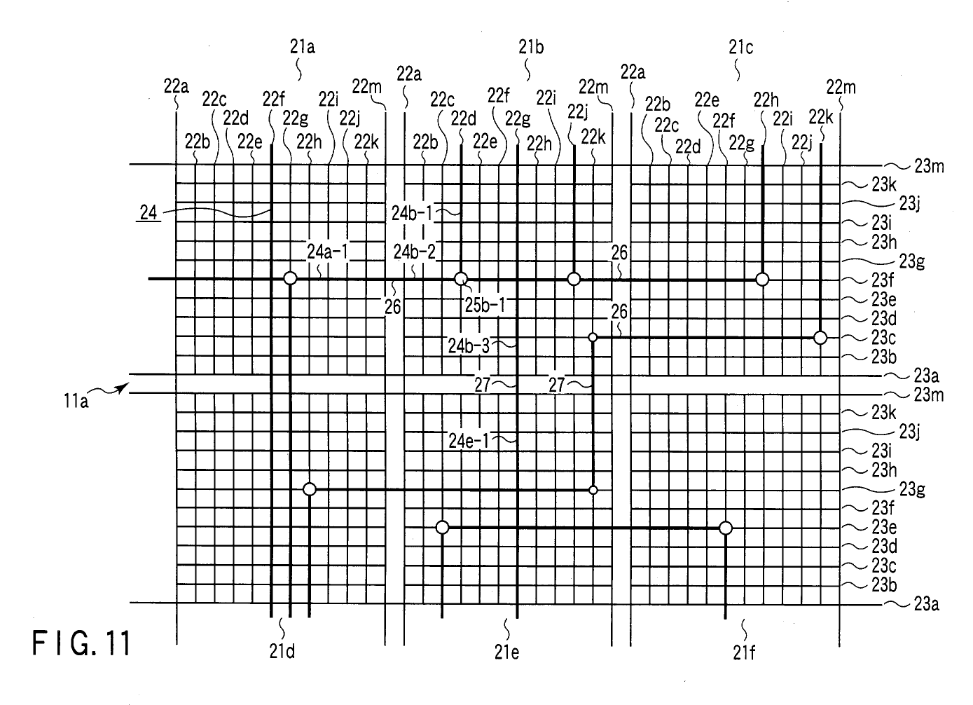

FIGS. 10 and 11 show a wiring method of a multi-layer wiring device according to a sixth embodiment of the present invention. In this example, a case wherein six wiring element blocks are arranged without overlapping is explained. FIG. 10 is a plane view showing the basic structure of the multi-layer wiring device and FIG. 11 is a plan view showing an example of the layout of signal lines in the multi-layer wiring device shown in FIG. 10.

In FIG. 10, six wiring element blocks 21a, 21b, . . . , 21f are arranged in a matrix form in a layout possible area (for example, power supply wiring area and signal wiring area between circuit blocks) on an LSI chip 11a. In the case of this example, each of the wiring element blocks 21a, 21b, . . . , 21f includes 12 (p(i), i=3 to k) metal wirings 22a, 22b, 22c, 22d, 22e, 22f, 22g, 22h, 22i, 22j, 22k, 22m formed of an M3 layer (nth layer), for example, and pitch-arranged in a first direction of the LSI chip 11a. Further, each of the wiring element blocks 21a, 21b, . . . , 21f includes 12 metal wirings 23a, 23b, 23c, 23d, 23e, 23f, 23g, 23h, 23i, 23j, 23k, 23m formed of an M2 layer ((n−1)th layer), for example, and pitch-arranged in a second direction substantially perpendicular to the first direction.

In each of the wiring element blocks 21a, 21b, . . . , 21f, metal wirings (first, second potential wirings) on the outermost sides of each layer are respectively connected to the common VSS wirings (second power supply line) 22a, 23a or to the common VDD wirings (first power supply line) 22m, 23m. In the case of this example, the VSS wiring 22a and VDD wiring 22m are laid by use of the M3 layer and the VSS wiring 23a and VDD wiring 23m are laid by use of the M2 layer. The metal wirings 22b, 22d, 22f, 22h, 22j and the metal wirings 22c, 22e, 22g, 22i, 22k other than the VSS wiring 22a and VDD wiring 22m among the 12 metal wirings 22a, 22b, 22c, 22d, 22e, 22f, 22g, 22h, 22i, 22j, 22k, 22m are respectively set at the VDD potential and VSS potential. The metal wirings 22b, 22c, 22d, 22e, 22f, 22g, 22h, 22i, 22j, 22k are assigned as wirings (s(j) wirings, (s(j)≦p(i)−2, j=1 to k−2)) which can also be used as signal lines. Likewise, the metal wirings 23b, 23d, 23f, 23h, 23j and the metal wirings 23c, 23e, 23g, 23i, 23k other than the VSS wiring 23a and VDD wiring 23m among the 12 metal wirings 23a, 23b, 23c, 23d, 23e, 23f, 23g, 23h, 23i, 23j, 23k, 23m are respectively set at the VDD potential and VSS potential. The metal wirings 23b, 23c, 23d, 23e, 23f, 23g, 23h, 23i, 23j, 23k are assigned as wirings (s(j) wirings, (s(j)≦p(i)−2, j=1 to k−2)) which can also be used as signal lines.

Thus, in each of the wiring element blocks 21a, 21b, . . . , 21f, adjacent metal wirings are respectively supplied with the VDD potential and VSS potential and a decoupling capacitor between VDD and VSS caused by a capacitor between parallel extending wirings is formed. In order to increase the capacitance of the decoupling capacitor between VDD and VSS, it is desirable to arrange the metal wirings of each layer with minimum pitch. This is because the capacitance of the capacitor between the wirings becomes maximum.

In the multi-layer wiring device with the above configuration, for example, when signal lines (indicated by thick lines) 24 are laid as shown in FIG. 11, connection of the signal lines in the same block can be made by providing in-block connection Vias (contact wirings) between the M2 layer and the M3 layer. For example, metal wirings 24b-1, 24b-2 in the wiring element block 21b are connected together by providing an in-block connection Via 25b-1 between the M2 layer and the M3 layer which lie in the upper and lower positions. Further, connection of signal lines between blocks which are adjacent in the first direction can be made by providing a block-block connection wiring (M2 layer) between the adjacent blocks. For example, the metal wiring 24b-2 in the wiring element block 21b and the metal wiring 24a-1 in the wiring element block 21a are connected together by providing a block-block connection wiring 26 between the two blocks 21a and 21b. Likewise, connection of signal lines between blocks which are adjacent in the second direction can be made by providing a block-block connection wiring (M3 layer) between the adjacent blocks. For example, the metal wiring 24b-3 in the wiring element block 21b and the metal wiring 24e-1 in the wiring element block 21e are connected together by providing a block-block connection wiring 27 between the two blocks 21b and 21e.

In the case of this example, in the wiring element blocks 21a, 21b, . . . , 21f, through hole contacts used to supply the VDD potential or VSS potential are previously removed from all of the metal wirings used as the signal lines 24 (refer to FIGS. 3A and 3B). That is, as described before, for example, in the wiring element blocks 21b, supply of the VDD potential and VSS potential to the metal wirings 22d, 22g, 22j, 22k, 23c, 23f used as the signal lines 24b-1, 24b-2, is cut off.

In order to form the in-block connection Via 25b-1 and block-block connection wirings 26, 27, a low-resistance conductive material is used. Alternatively, a fuse material which can be programmed to be changed from the high resistance state to a low resistance state can be used.

With the above configuration, not only the multi-layer wiring device having a large decoupling capacitor is simply arranged in a signal wiring area between circuit blocks and power supply wiring area on the LSI chip 11a, but also a desired signal line 24 can be easily arranged with a high degree of freedom.

Further, metal wirings which are supplied with the VDD potential or VSS potential can be easily provided near the desired signal line 24. That is, the metal wirings which are supplied with the VDD potential or VSS potential are provided near the desired signal line 24 without fail. By thus providing the metal wirings, the metal wirings which are supplied with the VDD potential or VSS potential can be used to function as shielding wirings. As a result, introduction of electromagnetic field noise into the signal line 24 can be suppressed and the advantage that signal integrity can be significantly enhanced can be attained. This is suitable for attainment of an automatic wiring connection algorithm which is extremely free from erroneous operation due to noise.

Further, since the wiring connection path (signal line path) can be freely changed by changing the position of the contact wiring, it is particularly effective for shortening the designing period of ASICs.

In the case of the present embodiment, since the metal wirings assigned as the signal lines are electrically connected together in the same block, they can be basically used as only one signal line. In this respect, the present embodiment has a disadvantage that the wiring density is low in comparison with the conventional wiring method. However, the above defect can be easily overcome by adding means for cutting off (electrically isolating) the metal wiring in a desired position in the block.

A case wherein the M2 layer, M3 layer are used is explained, but this is not limitative. For example, this invention can also be applied to a wiring element block having a multi-layer wiring structure of three or more layers.

(Seventh Embodiment)

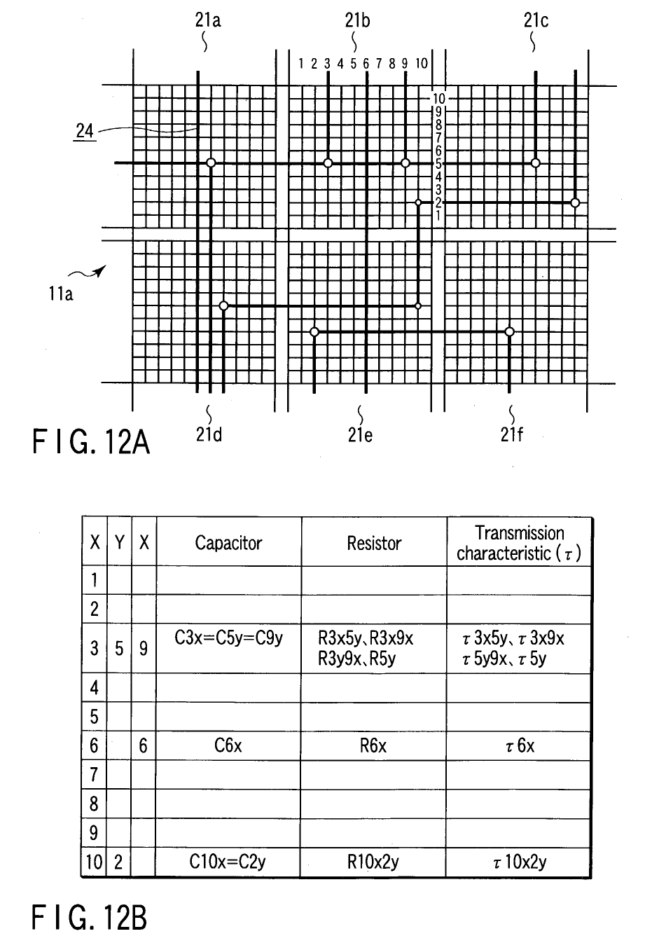

FIGS. 12A and 12B illustrate a wiring characteristic analyzing/predicting method of a multi-layer wiring device according to a seventh embodiment of the present invention. FIG. 12A shows an example of the arrangement of signal lines in the multi-layer wiring device (refer to FIG. 11). In the case of this example, each of wiring element blocks 21a, 21b, . . . , 21f includes 12 metal wirings 22a, 22b, 22c, 22d, 22e, 22f, 22g, 22h, 22i, 22j, 22k, 22m which are pitch-arranged in a first direction of an LSI chip 11a and 12 metal wirings 23a, 23b, 23c, 23d, 23e, 23f, 23g, 23h, 23i, 23j, 23k, 23m which are pitch-arranged in a second direction. Therefore, even when all of the metal wirings (except the VSS wirings 22a, 23a and VDD wirings 22m, 23m) are used as signal lines, each of the wiring element blocks 21a, 21b, . . . , 21f can be used as a basic block having 40 terminals. FIG. 12B shows one example of a characteristic library for the wiring element block 21b which can be derived from the example of the arrangement of FIG. 12A. In this case, the ten metal wirings 22b to 22k in the first direction are assigned to X values (1 to 10) and the ten metal wirings 23b to 23k in the second direction are assigned to Y values (1 to 10).

As a signal transfer function (input/output signal propagation characteristic) used as a parameter to make wiring characteristic analysis/prediction of the multi-layer wiring device, a transmission characteristic τ (delay value) is used in this example. As the signal transfer function, an S parameter can also be used.

Thus, signal transfer functions between 40 terminals of the wiring element block are previously calculated for every combinations and the results of the calculation are managed as a library with an emphasis on the results of the calculation in the wiring cell. Therefore, the characteristic of the signal line arranged in a desired block can be precisely predicted by performing a simple four-function operation according to the wiring connection path while referring to the library.

The characteristic library is not limited to the above library and a library of a different form can be used.

As described above, in each of the above embodiments, the metal wirings of the wiring layers which lie in the upper and lower positions are shown to intersect at right angles, but they are not necessarily arranged to intersect at right angles if they are not arranged parallel to each other.

Further, the VDD wiring and VSS wiring are arranged on the outermost sides of each wiring layer, but this is not limitative. For example, a metal wiring which crosses all of the metal wirings of another wiring layer can be used as the VDD wiring or VSS wiring.

In the multi-layer wiring device, for example, if a capacitor is connected between the signal lines other than the VDD power supply line and VSS power supply line, the capacitor can be used as a capacitive element having large capacitance and an excellent high-frequency characteristic. Particularly, the capacitor can be used as a feedback capacitor in an analog circuit or a capacitive element of a switched capacitor circuit. Further, the capacitor can be used as a voltage boosting capacitor of a digital circuit.

The M1 layer, M2 layer on the lower layer side can be configured as power supply grids. Further, the M1 layer, M2 layer can be configured as local wirings inside and outside the cell.

(Eighth Embodiment)

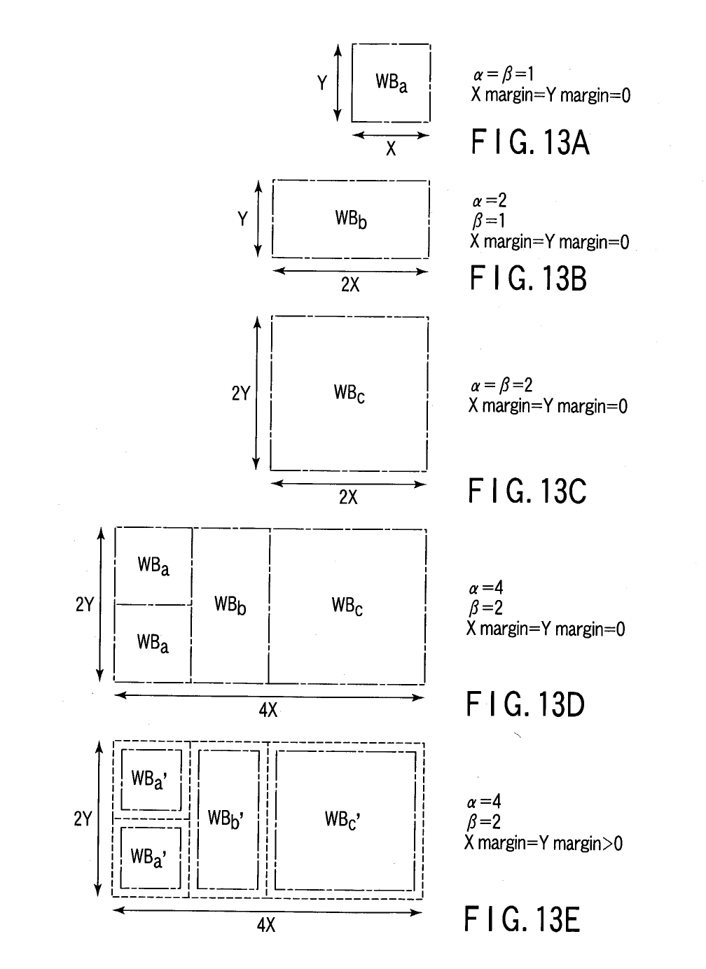

FIGS. 13A to 13E show another configuration of a multi-layer wiring device (wiring element block of multi-layer wiring structure) according to an eighth embodiment of the present invention. In this example, a case wherein a wiring element block has a variously changed size is explained as an example.

The wiring element block is defined based on the following expression (1) according to the plane size as viewed from above.

(X×2^{α-1}Xmargin)×(Y×2^{β-1}−Ymargin) . . . (1)

In the above expression (1), (X×2^{α-1}−Xmargin) indicates the length of the wiring element block in a first direction and (Y×2^{β-1}−Ymargin) indicates the length thereof in a second direction. Further, α, β are positive integers and Xmargin, Ymargin≧0.

FIGS. 13A to 13C show examples of the wiring element block whose sizes are variously changed. That is, in the case of α=β=1 and Xmargin=Ymargin=0, the wiring element block WBa comes to have the minimum plane size (X×Y) which is used as the basic size (minimum unit). In the case of α=2, β=1 and Xmargin=Ymargin=0, the wiring element block WBb comes to have the size (2X×Y) which is twice the basic size in the first direction. In the case of α=2, β=2 and Xmargin=Ymargin=0, the wiring element block WBc comes to have the size (2X×2Y) which is twice the basic size in both of the first and second directions.

FIG. 13D shows an example of a case wherein some wiring element blocks WBa, WBb, WBc having different plane sizes are combined to form a desired circuit. For example, when it is desired to form a circuit having a size of (4X×2Y), it can be easily configured by combining two wiring element blocks WBa, one wiring element block WBb and one wiring element block WBc. Thus, in order to configure various forms of wiring element blocks, a plurality of wiring element blocks WBa, WBb, WBc having different plane sizes are previously prepared. As a result, when a desired circuit is configured, the circuit can be efficiently configured by adequately combining the wiring element blocks WBa, WBb, WBc.

FIG. 13E shows another example of a case wherein wiring element blocks having different plane sizes are combined to form a desired circuit. In the case of this example, wiring element blocks WBa′, WBb′, WBc′ are configured to have connection margins (Xmargin, Ymargin). In the case of the wiring element blocks WBa′, WBb′, WBc′ having the connection margins, it becomes possible to easily connect the wiring element blocks WBa′, WBb′, WBc′ to each other after the desired circuit is configured.

In either case, the plane sizes of the wiring element blocks can be freely set and are not limited to the above plane sizes.

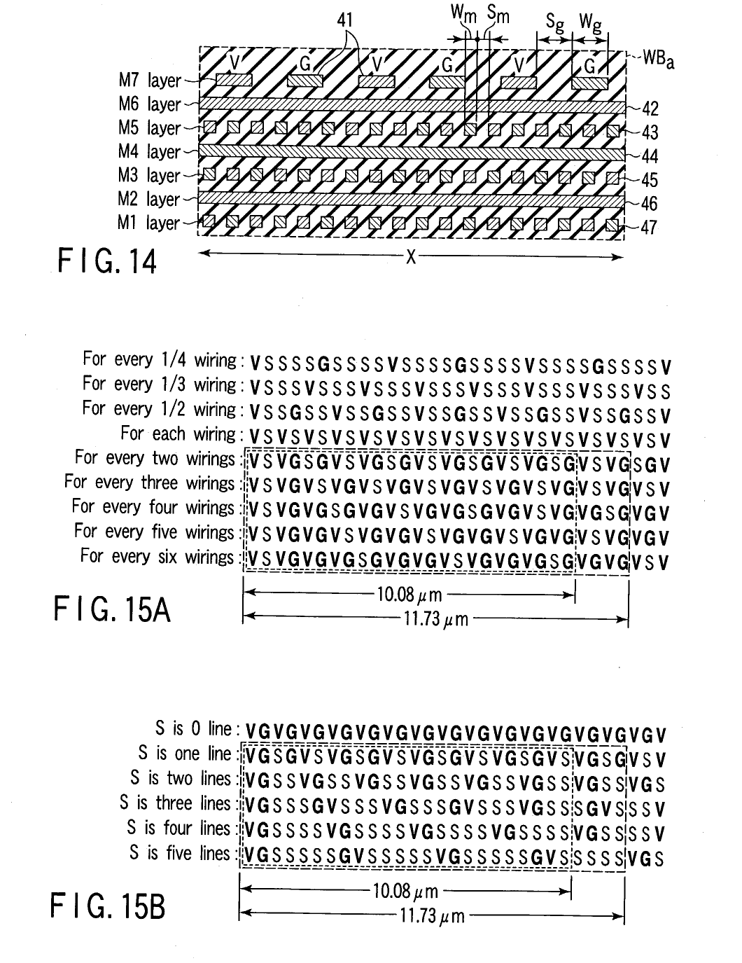

FIG. 14 shows a basic structure of the wiring element block WBa (minimum unit) shown in FIG. 13A. As shown in FIG. 14, the wiring element block WBa has a seven-layered structure of M1 layer to M7 layer and the uppermost layer (M7 layer) is used as a power supply grid. In the M7 layer, an even number of metal wirings 41 having minimum width Wg,min are pitch-arranged at the same pitch of minimum space Sg,min. The metal wirings 41 are used as VDD power supply lines (V) supplied with VDD potential from the VDD potential supply source and VSS power supply lines (G) supplied with VSS potential from the VSS potential supply source. In the M6 layer to M1 layer, even numbers of metal wirings 42 to 47 having the minimum width Wm,min are pitch-arranged at the same pitch of minimum space Sm,min. Each of the metal wirings 42 to 47 is supplied with the VDD potential from the VDD power supply line or the VSS potential from the VSS power supply line via a through contact hole (not shown).

In the case of this example, the minimum width Wm,min of the metal wirings 42 to 47 is set to (⅓)·Wg,min, for example, with the minimum width Wg,min of the metal wiring 41 used as a reference. Likewise, the minimum space Sm,min of the metal wirings 42 to 47 is set to (⅓)·Sg,min, for example, with the minimum space Sg,min of the metal wiring 41 used as a reference. Further, the minimum space of both end portions of the M7 layer is set to (½)·Sg,min and the minimum space of both end portions of each of the M6 layer to M1 layer is set to (½)·Sm,min. As a result, even when a plurality of wiring element blocks WBa are arranged all over the layout area without overlapping, the relation between the VDD potential and the VSS potential which are alternately supplied can be maintained.

Now, the plane size of the wiring element block WBa is specifically analyzed with reference to FIGS. 15A and 15B.

FIG. 15A shows an example of the way to assign signal lines (S) in the wiring element block WBa in which the VDD wirings (V) and VSS wirings (G) are alternately arranged. In this case, for example, a case wherein each signal line (S) is arranged at intervals of every six metal wirings of a certain wiring layer is indicated by “for every six wirings” and a case wherein every four signal lines (S) are arranged for each metal wiring is indicated by “for every ¼ wiring”.

FIG. 15B shows an example of the way to assign signal lines (S) in a case where the VDD wirings (V) and VSS wirings (G) are always provided to make pairs in the wiring element block WBa in which the VDD wirings (V) and VSS wirings (G) are alternately arranged. In this case, for example, a case wherein five signal lines (S) are arranged between two adjacent pairs of metal wirings of a certain wiring layer is indicated by “S is five lines” and a case wherein no signal line (S) is arranged is indicated by “S is 0 line”.

When a plurality of wiring element blocks WBa are arranged, it is better to set the number of metal wirings 41 of the M7 layer to 24 by taking into consideration that either the VDD wiring (V) or VSS wiring (G) is arranged on the end portion of each of the wiring element blocks WBa and the arrangement of the VDD wirings (V) and VSS wirings (G) substantially makes a repetitive pattern. Further, it is better to set the number of metal wirings 41 of the M7 layer to approximately 28 by taking the connection margin into consideration.

In each case of the above examples, if the calculation is made on the assumption that the number of metal wirings 41 of the M7 layer is set to 24 in the wiring element block WBa and the minimum width Wg,min and the minimum space Sg,min of the metal wirings 41 are set to 0.42 μm, one side of the plane size of the wiring element block WBa is set to 10.08 μm. Further, when the number of metal wirings 41 is set to 28, one side of the plane size of the wiring element block WBa is set to 11.73 μm.

(Ninth Embodiment)

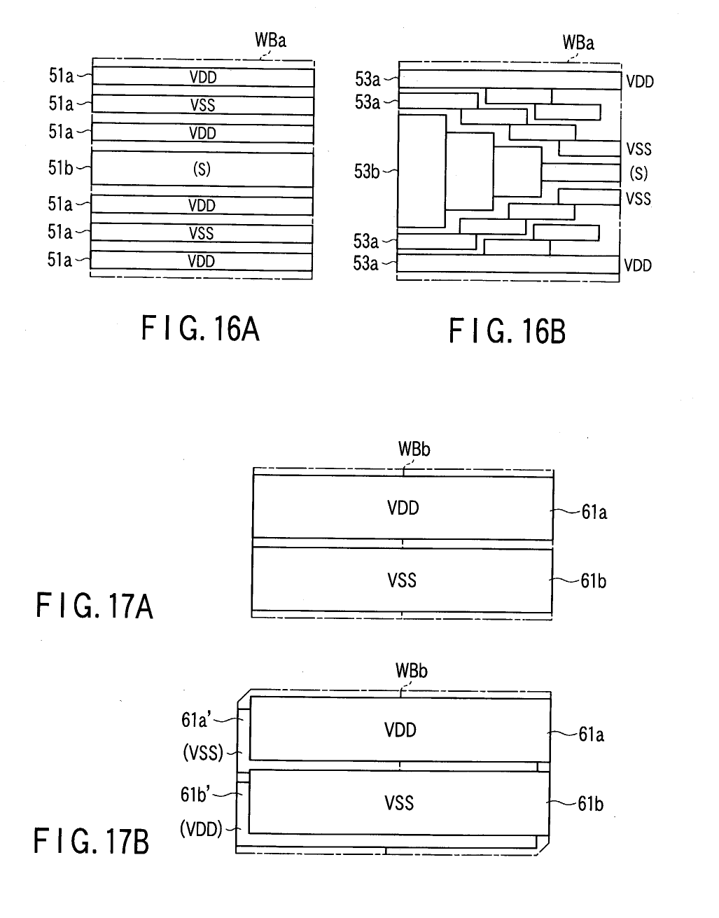

FIGS. 16A and 16B show another configuration of a multi-layer wiring device (wiring element block of multi-layer wiring structure) according to a ninth embodiment of the present invention. In this example, a case wherein metal wirings of a certain wiring layer are variously modified is explained by taking the wiring element block with the size shown in FIG. 13A as an example.

FIG. 16A shows an example of a case wherein a metal wiring 51b among a plurality of metal wirings 51a, 51b is formed with a larger wiring width than the other metal wiring 51a in the wiring element block WBa, for example. In this case, the metal wiring 51b having a larger wiring width is used as a signal line. If the metal wiring 51b used as the signal line is thus formed as a wide wiring, the metal wiring becomes suitable for high-speed transmission of a signal. Particularly, by arranging the VDD wirings or VSS wirings on both sides of the metal wiring 51b, it becomes possible to obtain stable capacitance or inductance.

FIG. 16B is a view showing an example of a case wherein a metal wiring 53b among a plurality of metal wirings 53a, 53b is formed as a tapered wiring in the wiring element block WBa, for example. By thus forming the metal wiring 53b as the tapered wiring, the signal propagation delay as in a clock line can be optimized. Also, in this case, by arranging the VDD wirings or VSS wirings on both sides of the metal wiring 53b, it becomes possible to obtain stable capacitance or inductance.

(Tenth Embodiment)

FIGS. 17A and 17B show another configuration of a multi-layer wiring device (wiring element block of multi-layer wiring structure) according to a tenth embodiment of the present invention. In this example, a case wherein metal wirings of a certain wiring layer are variously modified is explained by taking the wiring element block with the size shown in FIG. 13B as an example.

FIG. 17A shows an example of a case wherein two metal wirings 61a, 61b with large wiring width are provided for at least one wiring layer in the wiring element block WBb, for example. The metal wirings 61a, 61b are arranged in parallel to extend in a first direction of the wiring element block WBb. In this case, the metal wiring 61a is used as a VDD wiring and the metal wiring 61b is used as a VSS wiring. By thus forming the metal wirings 61a, 61b as wirings with a large wiring width for the VDD wiring and VSS wiring, a power supply voltage drop due to impedance (resistance) of the power supply line can be suppressed.

FIG. 17B shows an example of a case wherein two pairs of metal wirings 61a, 61b and 61a′ 61b′ with a large wiring width are provided for at least two wiring layers in the wiring element block WBb, for example. The metal wirings 61a, 61b and 61a′, 61b′ are arranged in parallel to extend in a first direction of the wiring element block WBb. In this case, the metal wiring 61a′ of one of the two wiring layers is used as a VDD wiring and the metal wiring 61b′ thereof is used as a VSS wiring. Further, the metal wiring 61a of the other wiring layer is used as a VSS wiring and the metal wiring 61b thereof is used as a VDD wiring. By thus forming the metal wirings 61a, 61b and 61a′, 61b′ of the upper and lower wiring layers as wirings with a large wiring-width for the VDD wirings and VSS wirings, not only the impedance of the power supply wiring is lowered but also a decoupling capacitor between VDD and VSS can be formed with large capacitance.

(Eleventh Embodiment)

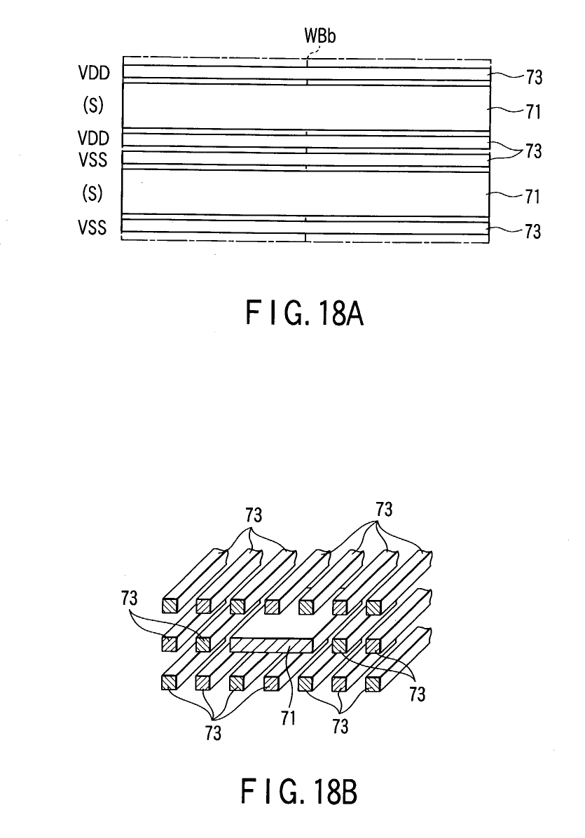

FIGS. 18A and 18B show another configuration of a multi-layer wiring device (wiring element block of multi-layer wiring structure) according to an eleventh embodiment of the present invention.

FIG. 18A shows an example of a case wherein a plurality of metal wirings 73 including N-bit (N) metal wirings 71 with a large wiring width are provided for at least one wiring layer in the wiring element block WBb of the size shown in FIG. 13B, for example. The metal wirings 71, 73 are arranged in parallel to extend in a first direction of the wiring element block WBb. In this case, the metal wirings 71 are used as bus signal lines. By thus preparing the wiring element block WBb having wirings with a large wiring width (metal wirings 71), high-speed bus signal lines can be arranged with high efficiency when a desired circuit is formed.

By arranging one VDD wiring or VSS wiring or a plurality of VDD wirings or VSS wirings between the metal wirings 71 and using the VDD wirings or VSS wirings as shielding wirings, a high-inductance shielding effect can be attained.

Particularly, for example, as shown in FIG. 18B, when VDD wirings or VSS wirings are arranged in the same direction on the upper and lower sides of the metal wiring 71, the bus signal line can be perfectly capacitively shielded and the loop inductance can be minimized.

Of course, it is possible to adequately change the number of bus signal lines, the width thereof and the spacing therebetween.

(Twelfth Embodiment)

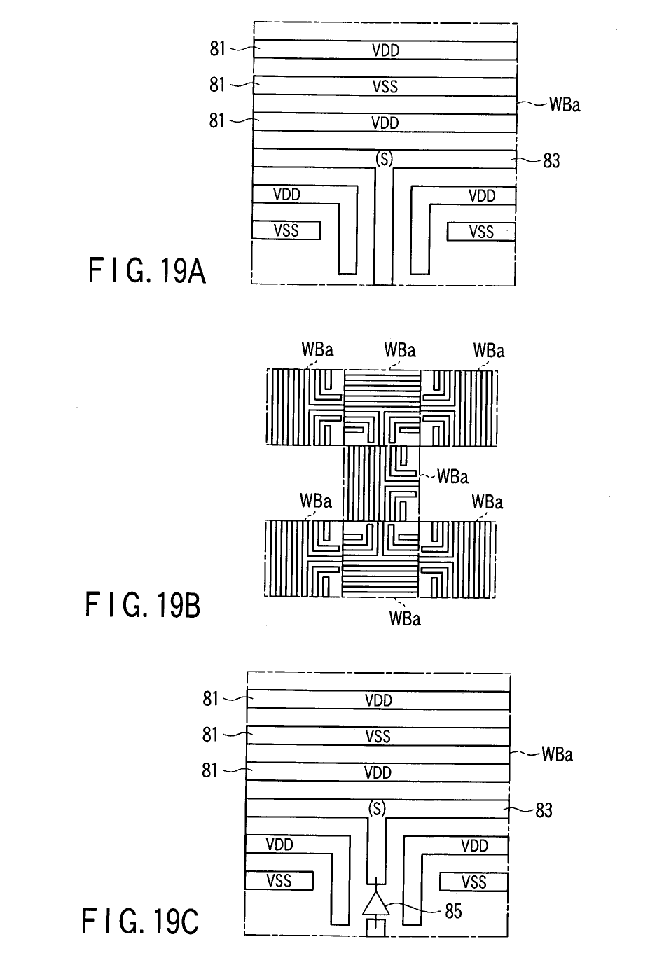

FIGS. 19A to 19C show another configuration of a multi-layer wiring device (wiring element block of multi-layer wiring structure) according to a twelfth embodiment of the present invention.

FIG. 19A shows an example of a case wherein at least one of a plurality of metal wirings 81 is formed as a T-shaped metal wiring (T-type wiring) 83 in at least one wiring layer in the wiring element block WBa of the size shown in FIG. 13A, for example. In this case, the T-type wiring 83 is used for H-tree of a clock wiring or the like. By thus preparing the wiring element block WBa having the T-type wiring 83, the directions of the wirings can be efficiently switched when a desired circuit is formed as shown in FIG. 19B, for example. In switching the directions of the wirings, high-speed transmission of a signal can be attained in comparison with a method using vias since delay caused by the presence of vias and via resistance are not increased.

Further, in the wiring element block WBa having the T-type wiring 83 shown in FIG. 19A, a buffer 85 can be inserted into the T-type wiring 83 as shown in FIG. 19C, for example.

If a driver or receiver is inserted instead of the buffer 85, the utility value of the T-type wiring 83 used as a signal line having optimum delay time can be enhanced.

Further, the T-type wiring 83 is formed on the same wiring layer in the above example, but it can be formed by use of two different wiring layers. In addition, it is also possible to taper the T-type wiring 83.

(Thirteenth Embodiment)

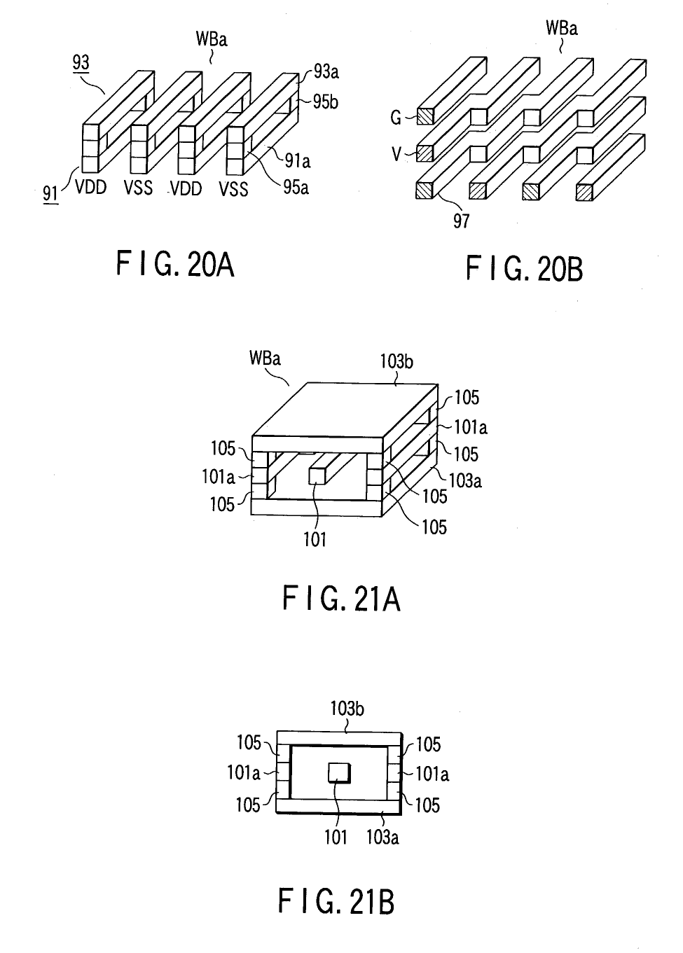

FIGS. 20A and 20B show another configuration of a multi-layer wiring device (wiring element block of multi-layer wiring structure) according to a thirteenth embodiment of the present invention.

FIG. 20A shows an example of a case wherein a plurality of metal wirings 91a, 93a which are pitch-arranged in the same direction on at least two wiring layers 91, 93 adjacent in a vertical direction are connected to each other by use of vias (through contact holes) 95a, 95b in the wiring element block WBa of the size shown in FIG. 13A, for example. The pairs of the metal wirings 91a and 93a are alternately supplied with different potentials. With this configuration, since the resistance of each pair of the metal wirings 91a and 93a can be reduced, the wiring element block WBa can be formed to be suitable for formation of a power supply line whose impedance is desired to be lowered.

FIG. 20B shows an example of a case wherein a plurality of metal wirings 97 which are pitch-arranged on at least one wiring layer are formed in a stepwise bent form in the wiring element block WBa of the size shown in FIG. 13A, for example. The metal wirings 97 are alternately supplied with different potentials. With this configuration, since the capacitive crosstalk can be lowered, a decoupling capacitor between VDD and VSS can be formed with a large capacitance and the inductance thereof can be made small, the wiring element block WBa can be formed to be suitable for formation of a bus signal line in which it is desired to suppress the crosstalk.

(Fourteenth Embodiment)

FIGS. 21A and 21B show another configuration of a multi-layer wiring device (wiring element block of multi-layer wiring structure) according to a fourteenth embodiment of the present invention.

FIG. 21A shows an example of a case wherein the surrounding portion of a metal wiring 101 used as a signal line is completely shielded in the wiring element block WBa of the size shown in FIG. 13A, for example. In the case of this example, wiring layers 103a, 103b which lie on the lower and upper layer sides of the metal wiring 101 are formed as a plane. Further, metal wirings 101a which lie on the same layer as the metal wiring 101 are each connected to the wiring layers 103a, 103b through vias 105. As a result, as shown in FIG. 21B, for example, the surrounding portion of the metal wiring 101 can be completely shielded by use of a VDD or VSS wiring. With this configuration, since capacitive noise or inductive noise with respect to an extremely sensitive signal line (transmission line) can be shielded almost idealistically, the wiring element block WBa can be formed to be suitable for formation of a signal line which is desired to be free from noise.

(Fifteenth Embodiment)

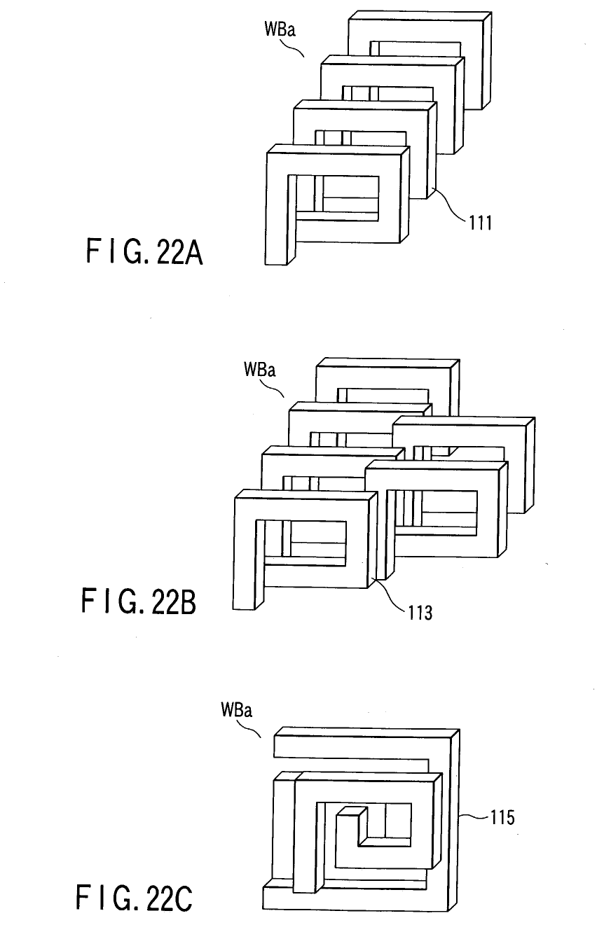

FIGS. 22A to 22C show another configuration of a multi-layer wiring device (wiring element block of multi-layer wiring structure) according to a fifteenth embodiment of the present invention.

FIG. 22A shows an example of a case wherein a horizontal coil (inductor) 111 is incorporated in the wiring element block WBa of the size shown in FIG. 13A, for example. By adjusting the number of turns and the size of the winding, the coil 111 of a desired size can be attained. With this configuration, the wiring element block WBa which is suitable for formation of a coil can be attained.

FIG. 22B shows an example of a case wherein a horizontal transformer 113 is incorporated in the wiring element block WBa of the size shown in FIG. 13A, for example. With this configuration, the wiring element block WBa which is suitable for formation of a transformer can be attained.

FIG. 22C shows an example of a case wherein a vertical transformer 115 is incorporated in the wiring element block WBa of the size shown in FIG. 13A, for example. With this configuration, a wiring element block WBa which is suitable for formation of a transformer can be attained.

In each of the above cases, the influence on an adjacent wiring element block can be alleviated by arranging a VSS wiring around the wiring element block WBa.

(Sixteenth Embodiment)

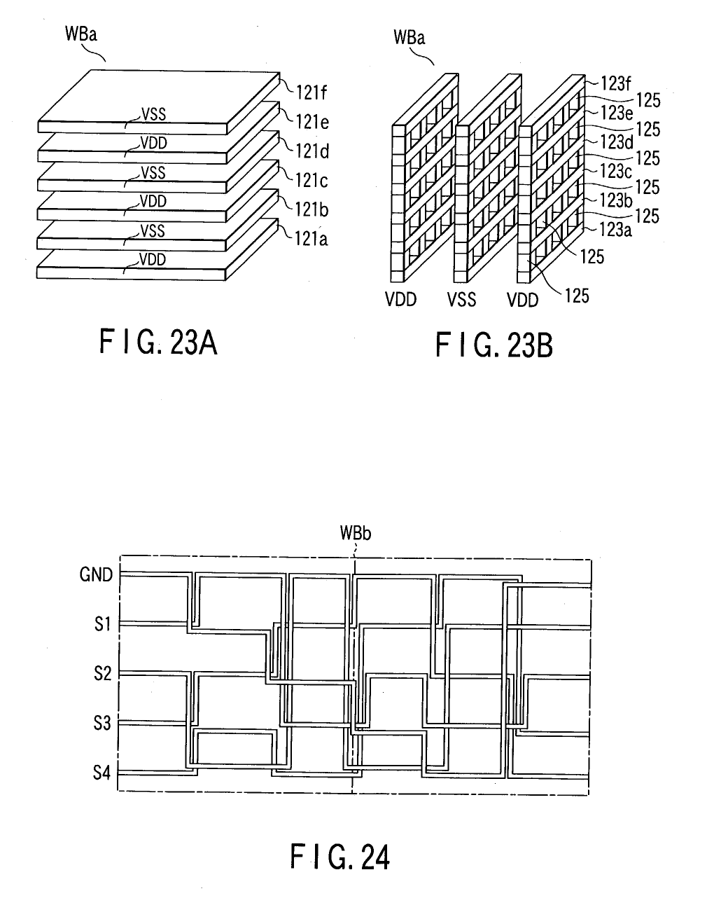

FIGS. 23A and 23B show another configuration of a multi-layer wiring device (wiring element block of multi-layer wiring structure) according to a sixteenth embodiment of the present invention.

FIG. 23A shows an example of a case wherein plane capacitors are formed in the wiring element block WBa of the size shown in FIG. 13A, for example. That is, plane wirings 121a, 121b, 121c, 121d, 121e, 121f of a large width are used as metal wirings in respective wiring layers and different potentials are alternately supplied to the plane wirings 121a, 121b, 121c, 121d, 121e, 121f. With this configuration, a desired capacitance pattern can be easily formed and the wiring element block WBa which is suitable for formation of a large capacitor in a small area can be attained.

FIG. 23B shows an example of a case wherein vertical capacitors are formed in the wiring element block WBa of the size shown in FIG. 13A, for example. In the case of this example, a plurality of metal wirings 123a, 123b, 123c, 123d, 123e, 123f of respective wiring layers which are pitch-arranged in the same direction are connected to one another through vias (through hole contacts) 125 to form a plurality of vertical capacitors. Different potentials are alternately supplied to the vertical capacitors. With this configuration, the wiring element block WBa which is suitable for formation of an RF (radio frequency) amplifier or the like can be attained.

(Seventeenth Embodiment)

FIG. 24 shows another configuration of a multi-layer wiring device (wiring element block of multi-layer wiring structure) according to a seventeenth embodiment of the present invention. A case wherein a 4-bit twisted bundle wiring (one ground line GND and four signal lines S1 to S4) is formed in the wiring element block WBb of the size shown in FIG. 13B, for example, is explained as an example.

That is, the twisted bundle wiring has a twisted structure in which the ground line GND and the signal lines S1 to S4 are interlaced, the magnetic fluxes of the signal lines S1 to S4 cancel one another and the ground line GND used as a current feedback path is arranged near the signal lines S1 to S4. For example, the ground line GND is formed by use of a pair of VDD and VSS wirings. With the above configuration, since inductive crosstalk can be reduced by use of a smaller number of shield wirings (a smaller number of ground return wirings), the wiring element block WBb suitable for formation of a signal line in which it is desired to suppress inductive crosstalk can be attained.

The number of bits of the twisted bundle wiring is not limited to four and a 2^{N}-bit twisted bundle wiring can be formed. In this case, signal lines of a number corresponding to the number of bits are prepared and one or more ground lines are provided for each bit to form a bundle.

(Eighteenth Embodiment)

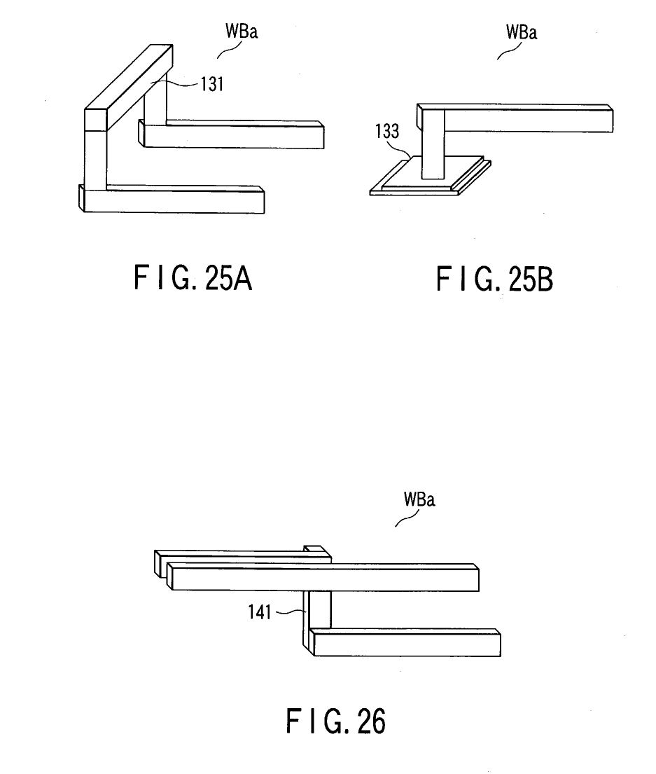

FIGS. 25A and 25B show another configuration of a multi-layer wiring device (wiring element block of multi-layer wiring structure) according to an eighteenth embodiment of the present invention. A case wherein a wiring structure is formed to cope with an antenna in the wiring element block WBa of the size shown in FIG. 13A, for example, is explained as an example.

FIG. 25A shows an example of a case wherein a wiring layer switching wiring 131 used to prevent gate breakdown caused by accumulation of electrostatic charges called an “antenna” in a certain condition in a metal damascene step for forming a semiconductor device is formed as a wiring structure designed to cope with the antenna and incorporated in the wiring element block WBa. With the above configuration, the wiring element block WBa suitable for countermeasures against the antenna can be attained.

(Nineteenth Embodiment)

FIG. 26 shows another configuration of a multi-layer wiring device (wiring element block of multi-layer wiring structure) according to a nineteenth embodiment of the present invention. A case wherein a parallel-wiring switching wiring is formed in the wiring element block WBa of the size shown in FIG. 13A, for example, is explained as an example.

That is, a switching wiring 141 to switch parallel wirings which are used to take countermeasures against capacitive crosstalk is incorporated in the wiring element block WBa. From the viewpoint of area, it is effective to take countermeasures against the crosstalk by switching wiring layers. Therefore, with the above configuration, the wiring element block WBa suitable for formation of parallel wirings which are required to take countermeasures against the crosstalk can be attained.

(Twentieth Embodiment)

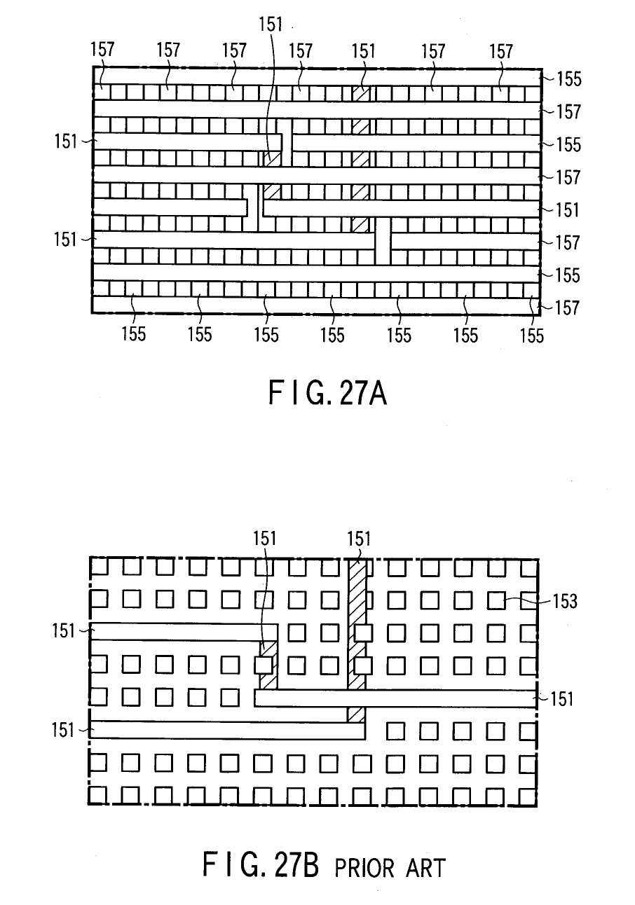

FIGS. 27A and 27B show a wiring layout design method according to a twentieth embodiment of the present invention. FIG. 27A is a layout view for illustrating the design method according to the present embodiment and FIG. 27B is a layout view showing an existing design method.

So far, as shown in FIG. 27B, dummy metal wirings 153 are inserted in a space area in which no metal wirings (signal lines) 151 are arranged in order to meet the density rule after the end of the arrangement of wirings.

In the layout design method according to the present embodiment, for example, as shown in FIG. 27A, VDD wirings 155 and VSS wirings 157 are arranged over the entire portion of a space area in which no metal wirings 151 are arranged for all of the layers. The VDD wirings 155 or VSS wirings 157 are arranged with an angle of 90° shifted from each other for each layer. Further, the VDD wirings 155 and VSS wirings 157 are alternately arranged. At this time, spacing is adjusted by arranging the VDD wirings 155 or VSS wirings 157 to extend in parallel with the minimum space with respect to the power supply line of the same layer and arranging the VDD wirings 155 or VSS wirings 157 to extend in parallel with a space larger than the minimum space with respect to the signal line, for example.

With the above configuration, the following merits can be expected. (1) The decoupling capacitor of the power supply can be increased. (2) The metal density can be made uniform. (3) Extraction of the wiring capacitor can be performed extremely easily at high speed. For example, the capacitance can be calculated on the assumption that the uppermost layer and the lowermost layer are ground planes. (4) Since the capacitance of the ground capacitor is increased, capacitive crosstalk can be reduced. (5) Since the power supply line and ground line are arranged near the signal line, inductance can be reduced.

It is also possible to arrange the VDD wirings 155 and VSS wirings 157 in the same direction in all of the layers or in part of the wiring layers.

Further, it is possible to insert pairs of VDD wirings and VSS wirings (VDD, VSS wiring pairs) between two adjacent parallel extending wirings (parallel extending wirings) by increasing the pitch between the wirings. Also, in this case, substantially the same effect as that obtained in the above case in which the VDD wirings 155 and VSS wirings 157 are arranged over the entire portion of the space area can be attained.

In addition, it is possible to fully arrange the VDD, VSS wiring pairs not only between the parallel extending wirings but also in the space area in which no metal wirings 151 are arranged.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-layer wiring device comprising:
a plurality of wiring layers which each include a plurality of wirings pitch-arranged in the same direction and are laminated on one another to make pitch-arrangement directions of the wirings of adjacent ones of the wiring layers cross each other, and
a plurality of contact portions which connect the plurality of wirings to one another to permit first and second potentials which are different from each other to be supplied to adjacent wirings of the plurality of wiring layers.

2. A multi-layer wiring device according to claim 1, wherein the adjacent wirings configure a decoupling capacitor between VDD and VSS.

3. A multi-layer wiring device according to claim 1, wherein the plurality of contact portions are provided at least between a wiring lying on the outermost side of one of the wiring layers and a wiring of the other wiring layer.

4. A multi-layer wiring device according to claim 1, wherein the plurality of contact portions include a first contact which is inevitably provided between a wiring lying on the outermost side of one of the wiring layers and a wiring lying on the outermost side of another wiring layer and a second contact which is selectively provided between a wiring lying on the outermost side of one of the wiring layers and a wiring lying in position other than the outermost side of another wiring layer.

5. A multi-layer wiring device according to claim 4, wherein the wiring lying on the outermost side of one of the wiring layers is a VDD, VSS wiring connected to a VDD, VSS potential supply source and the wiring lying in position other than the outermost side of the other wiring layer is a wiring which can be used as a signal line.

6. A multi-layer wiring device according to claim 1, wherein the plurality of wiring layers and the plurality of contact portions configure a wiring element block with a multi-layer wiring structure.

7. A multi-layer wiring device comprising:
a wiring element block with a multi-layer wiring structure configured by connecting a plurality of wiring layers which each include a plurality of wirings pitch-arranged in the same direction to one another in a vertical direction via a plurality of contact portions, the plurality of wiring layers being laminated on one another to make pitch-arrangement directions of the wirings of adjacent ones of the wiring layers cross each other and first and second potentials which are different from each other being supplied to adjacent wirings of the plurality of wiring layers.

8. A multi-layer wiring device according to claim 7, wherein the adjacent wirings configure a decoupling capacitor between VDD and VSS.

9. A multi-layer wiring device according to claim 7, wherein at least two wirings among the plurality of wirings of one of the plurality of wiring layers are supplied with VDD, VSS potentials from VDD, VSS potential supply sources, one of the two wirings is electrically connected to odd-numbered or even-numbered ones of a plurality of wirings of the wiring layer lying on the upper or lower layer side via through contact holes arranged at intersections of the wiring and the odd-numbered or even-numbered wirings and the other one of the two wirings is electrically connected to the even-numbered or odd-numbered ones of the plurality of wirings of the wiring layer lying on the upper or lower layer side via through contact holes arranged at intersections of the other wiring and the even-numbered or odd-numbered wirings.

10. A multi-layer wiring device according to claim 9, wherein the at least two wirings supplied with the VDD, VSS potentials lie on the outermost sides of the plurality of wirings.

11. A multi-layer wiring device comprising:
a wiring element block with a multi-layer wiring structure of m layers configured by connecting n (m≧n≧2) wiring layers which each include p(i) (i=3 to k) wirings pitch-arranged in the same direction to one another in a vertical direction via a plurality of contact portions, the n wiring layers being laminated on one another to make pitch-arrangement directions of the wirings of adjacent ones of the wiring layers cross each other, s(j) (s(j)≦p(i)−2, j=1 to k−2) wirings among the p(i) wirings being assigned as wirings which can be used as signal lines and first and second potentials which are different from each other being supplied to adjacent wirings except the signal lines.

12. The multi-layer wiring device according to claim 11, wherein the adjacent wirings configure a decoupling capacitor between VDD and VSS.

13. The multi-layer wiring device according to claim 11, wherein at least two wirings among the p(i) wirings of one of the n wiring layers are VDD, VSS wirings which are supplied with VDD, VSS potentials from VDD, VSS potential supply sources, the VDD wiring is electrically connected to those of the adjacent wirings other than the signal lines which are supplied with the VDD potential via through hole contacts arranged at the respective intersections in the wiring layer on the upper or lower layer side, and the VSS wiring is electrically connected to those of the adjacent wirings other than the signal lines which are supplied with the VSS potential via through hole contacts arranged at the respective intersections in the wiring layer on the upper or lower layer side.

14. A multi-layer wiring device according to claim 13, wherein the VDD, VSS wirings are arranged on the outermost sides of the p(i) wirings.

15. A multi-layer wiring device according to claim 11, wherein the wiring element block is arranged to overlap a power supply grid wiring of a semiconductor chip in plane.

16. A multi-layer wiring device according to claim 15, wherein the wiring element block is arranged in a signal wiring area between circuit blocks or power supply wiring area on the semiconductor chip.

17. A multi-layer wiring device according to claim 16, wherein the semiconductor chip has a plurality of wiring element blocks arranged in a matrix form without overlapping and includes VDD, VSS power supply lines to which VDD, VSS wirings of the plurality of wiring element blocks are respectively commonly connected, block-block connection wirings which connect signal lines extending between the plurality of wiring element blocks to one another, and contact wirings which connect signal lines extending over the upper and lower wiring layers in the same wiring element block to each other.

18. A wiring method of a multi-layer wiring device which includes a wiring element block with a multi-layer wiring structure of m layers configured by laminating n (m≧n≧2) wiring layers on one another by use of a plurality of contact portions to make pitch-arrangement directions of wirings of adjacent ones of the wiring layers cross each other, each of the wiring layers including p(i) (i=3 to k) wirings pitch-arranged in the same direction, s(j) (s(j)≦p(i)−2, j=1 to k−2) wirings among the p(i) wirings being assigned as wirings which can be used as signal lines and first and second potentials which are different from each other being supplied to adjacent wirings except the signal lines, comprising the steps of:
arranging a plurality of wiring element blocks in a matrix form without overlapping in a power supply wiring area or a signal wiring area between circuit blocks on a semiconductor chip,
respectively commonly connecting first and second potential wirings connected to first and second potential supply sources in the plurality of wiring element blocks via first and second power supply lines,
connecting signal lines which extend between the plurality of wiring element blocks to one another via block-block connection wirings, and
connecting signal lines which extend over upper and lower wiring layers in the same wiring element block to each other via contact wirings.

19. A wiring characteristic analyzing/predicting method of a multi-layer wiring device which is configured by arranging a plurality of wiring element blocks each having a multi-layer wiring structure of m layers in a matrix form without overlapping in a power supply wiring area or a signal wiring area between circuit blocks on a semiconductor chip, each of the wiring element blocks being configured by laminating n (m≧n≧2) wiring layers on one another by use of a plurality of contact portions to make pitch-arrangement directions of wirings of adjacent ones of the wiring layers cross each other, each of the wiring layers including p(i) (i=3 to k) wirings pitch-arranged in the same direction, s(j) (s(j)≦p(i)−2, j=1 to k−2) wirings among the p(i) wirings being assigned as wirings which can be used as signal lines and first and second potentials which are different from each other being supplied to adjacent wirings except the signal lines, respectively commonly connecting first and second potential wirings connected to first and second potential supply sources in the plurality of wiring element blocks via first and second power supply lines, connecting signal lines which extend between the plurality of wiring element blocks to one another via block-block connection wirings, and connecting signal lines which extend over upper and lower wiring layers in the same wiring element block to each other via contact wirings, comprising the steps of:
analyzing an input/output signal propagation characteristic corresponding to a wiring structure of signal lines in the same wiring element block, and
deriving a signal propagation characteristic of the signal lines extending between the plurality of wiring element blocks based on the result of analysis.

20. A wiring characteristic analyzing/predicting method of the multi-layer wiring device according to claim 19, wherein the result of analysis is sequentially managed as a library.

21. A multi-layer wiring device comprising:
a plurality of wiring element blocks of multi-layer wiring structure with different sizes each configured by laminating a plurality of wiring layers.

22. A multi-layer wiring device according to claim 21, wherein the plurality of wiring element blocks are freely combined to configure a desired circuit.

23. A multi-layer wiring device according to claim 21, wherein each of the plurality of wiring element blocks has a rectangular form and the plane sizes of the plurality of wiring element blocks are defined by (X×2^{α-1}−Xmargin)×(Y×2^{β-1}−Ymargin) (where α, β are positive integers and Xmargin, Ymargin≧0).

24. A multi-layer wiring device according to claim 23, wherein the size of the wiring element block becomes equal to a minimum basic size when α=β=1 and Xmargin=Ymargin=0.

25. A multi-layer wiring device according to claim 23, wherein the wiring element block of the basic size has a plurality of wiring layers, wirings of the uppermost one of the wiring layers each have a minimum width of Wg,min and are arranged with a minimum space of Sg,min, and wirings of the wiring layers other than the uppermost wiring layer each have a minimum width of (⅓)·Wg,min and are arranged with a minimum space of (⅓)·Sg,min.

26. A multi-layer wiring device according to claim 21, wherein at least one of the wiring layers of the plurality of wiring element blocks has a plurality of wirings and those of the plurality of wirings which are assigned as signal lines have larger width than those of the wirings which are assigned as power supply lines.

27. A multi-layer wiring device according to claim 26, wherein the wiring which is assigned as the signal line is surrounded by the wirings assigned as the power supply lines.

28. A multi-layer wiring device according to claim 21, wherein at least one of the wiring layers of the plurality of wiring element blocks has a plurality of wirings and those of the plurality of wirings which are assigned as signal lines are T-type wirings.

29. A multi-layer wiring device according to claim 21, wherein each of the plurality of wiring element blocks is configured by laminating a plurality of wiring layers each having a plurality of wirings pitch-arranged in the same direction on one another to make pitch-arrangement directions of the wirings of adjacent ones of the wiring layers cross each other.

30. A multi-layer wiring device according to claim 21, wherein each of the plurality of wiring element blocks is configured by laminating a plurality of wiring layers each having a plurality of wirings pitch-arranged in the same direction on one another to make pitch-arrangement directions of the wirings of adjacent ones of the wiring layers cross each other and the wirings lying in the upper and lower wiring layers are electrically connected to each other.
